(19) United States
(12) Patent Application Publication
(10) Pub. No.: US 2024/0421208 A1
(43) Pub. Date: Dec. 19, 2024

(54) SEMICONDUCTOR DEVICE AND METHOD FOR MANUFACTURING THE SEMICONDUCTOR DEVICE

(71) Applicant: SEMICONDUCTOR ENERGY LABORATORY CO., LTD., Atsugi-shi (JP)

(72) Inventors: Masami JINTYOU, Shimotsuga (JP); Masayoshi DOBASHI, Shimotsuga (JP); Junichi KOEZUKA, Tochigi (JP)

(21) Appl. No.: 18/738,930

(22) Filed: Jun. 10, 2024

(30) Foreign Application Priority Data
Jun. 16, 2023 (JP) 2023-099244

(51) Int. Cl. H01L 29/49; H01L 27/12; H01L 29/66; H01L 29/786

(52) U.S. Cl. CPC H01L 29/4908; H01L 29/66742; H01L 29/7869; H01L 27/1225

(57) ABSTRACT

A transistor that can be miniaturized and highly reliable is provided. A semiconductor device includes a transistor and a first insulating layer. The transistor includes first to third conductive layers, a semiconductor layer, and a second insulating layer. The first insulating layer includes a first layer and a second layer over the first layer. The first insulating layer is over the first conductive layer and includes a first opening reaching the first conductive layer. The second conductive layer is over the second layer. The semiconductor layer is in contact with the first and second conductive layers and with a side surface of the first layer inside the first opening. The second insulating layer covers the semiconductor layer in the first opening, and the third conductive layer covers the second insulating layer in the first opening. The first insulating layer includes a second opening at a position different from the first opening. The second insulating layer is in contact with the first layer inside the second opening. The first layer includes an oxide insulating film, and the second layer includes an insulating film having an oxygen barrier property.

### BACKGROUND OF THE INVENTION

### 1. Field of the Invention

One embodiment of the present invention relates to a semiconductor device and a method for manufacturing the semiconductor device. One embodiment of the present invention relates to a transistor and a method for manufacturing the transistor. One embodiment of the present invention relates to a display device including a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device generally means a device that can function by utilizing semiconductor characteristics.

### 2. Description of the Related Art

Miniaturization of transistors has been required. For example, a display device in which a transistor occupies only a small area of a pixel can have downsized pixels, leading to high resolution. In addition, in such a display device, the number of transistors provided per unit area can be increased, that is, a large number of transistors can be provided in the pixel without increasing the pixel size, so that a correction function or the like can be added to the pixel, for example.

In recent years, the resolution of a display panel has been increased. As a device that requires a high-resolution display panel, a device for virtual reality (VR) or augmented reality (AR) has been actively developed in recent years besides a tablet terminal, a smartphone, and a watch-type terminal. For a high-resolution display panel, a light-emitting element such as an organic electroluminescent (EL) element or a light-emitting diode (LED) is mainly used.

Patent Document 1 discloses a high-resolution display device using an organic EL device (also referred to as organic EL element).

### REFERENCE

### Patent Document

[Patent Document 1] International Publication No. 2016/038508

### SUMMARY OF THE INVENTION

In addition to miniaturization, an increase in reliability is required for transistors. In particular, in the case where a transistor is used in a pixel of a display device, a variation in electrical characteristics of the transistor might greatly affect variations in the color, brightness, and the like of each pixel. Such a display defect might degrade the sense of immersion in the case of a device for VR, in particular.

An object of one embodiment of the present invention is to provide a transistor that can be miniaturized. Another object is to provide a semiconductor device in which transistors can be arranged with high density. Another object is to provide a transistor with favorable electrical characteristics. Another object is to provide a transistor in which large current can flow. Another object is to provide a transistor with an extremely short channel length. Another object is to provide a transistor that occupies a small area. Another object is to provide a transistor that can be miniaturized and highly reliable. Another object is to provide a display device that can easily achieve higher resolution. Another object is to provide a highly reliable transistor, a highly reliable semiconductor device, or a highly reliable display device.

Another object is to provide a semiconductor device, a display device, or an electronic device having a novel structure. Another object is to at least alleviate at least one of problems in the conventional art.

Note that the description of these objects does not preclude the existence of other objects. In one embodiment of the present invention, there is no need to achieve all these objects. Objects other than these can be derived from the description of the specification, the drawings, the claims, and the like.

One embodiment of the present invention is a semiconductor device including a transistor and a first insulating layer. The transistor includes a first conductive layer, a second conductive layer, a third conductive layer, a semiconductor layer, and a second insulating layer. The first insulating layer includes a first layer and a second layer over the first layer. The first insulating layer is over the first conductive layer and includes a first opening reaching the first conductive layer. The second conductive layer is over the second layer. The semiconductor layer includes a part in contact with the first conductive layer, a part in contact with the second conductive layer, and a part in contact with a side surface of the first layer inside the first opening. The second insulating layer covers the semiconductor layer in the first opening, and the third conductive layer covers the second insulating layer in the first opening. The first insulating layer includes a second opening at a position different from the first opening. The second insulating layer includes a part in contact with the first layer inside the second opening. The first layer includes an oxide insulating film, and the second layer includes an insulating film having an oxygen barrier property.

In the above, the second opening is preferably at a position not overlapping with the second conductive layer in a plan view. In this case, the second opening preferably includes a part overlapping with the third conductive layer. The second opening preferably includes a part overlapping with the first conductive layer.

In any of the above, the second opening preferably penetrates the second layer and reaches the first layer. In this case, the first layer preferably includes a depression overlapping with the second opening. The second insulating layer is preferably in contact with a surface of the depression of the first layer inside the second opening.

In any of the above, the second opening preferably penetrates the second layer and the first layer. The second insulating layer is preferably in contact with a side surface of the first insulating layer inside the second opening.

In any of the above, the first insulating layer preferably includes a third layer below the first layer. The second opening preferably penetrates the second layer and the first layer and reaches the third layer.

In any of the above, the first insulating layer preferably includes a third layer below the first layer. The second opening preferably penetrates the second layer, the first layer, and the third layer.

In the above, the first layer preferably includes silicon oxide, and the second layer preferably includes silicon nitride or aluminum oxide.

In the above, the shortest distance between the first opening and the second opening is preferably greater than or equal to 0.1 μm and less than or equal to 100 μm.

Another embodiment of the present invention is a method for manufacturing a semiconductor device including the following steps: forming a first layer and a second layer over a first conductive layer; forming a second conductive layer over the second layer; forming, in the first layer and the second layer, a first opening reaching the first conductive layer and a second opening at a position apart from the first opening; performing heat treatment after forming a semiconductor film that covers the first opening and the second opening and is in contact with each of the first conductive layer and the second conductive layer; etching a part of the semiconductor film to expose the second opening; forming an insulating layer covering the semiconductor film and the second opening; and forming, over the insulating layer, a third conductive layer overlapping with the semiconductor layer. Here, the first layer includes an oxide insulating film, and the second layer includes an insulating film having an oxygen barrier property.

One embodiment of the present invention can provide a transistor that can be miniaturized. Another embodiment can provide a semiconductor device in which transistors can be arranged with high density. Another embodiment can provide a transistor with favorable electrical characteristics. Another embodiment can provide a transistor in which large current can flow. Another embodiment can provide a transistor with an extremely short channel length.

Another embodiment can provide a transistor that occupies a small area. Another embodiment can provide a transistor that can be miniaturized and highly reliable. Another embodiment can provide a display device that can easily achieve higher resolution. Another embodiment can provide a highly reliable transistor, a highly reliable semiconductor device, or a highly reliable display device.

One embodiment of the present invention can provide a semiconductor device, a display device, or an electronic device having a novel structure. According to one embodiment of the present invention, at least one of problems in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

FIGS. 1A to 1C illustrate a structure example of a semiconductor device.

FIGS. 2A and 2B illustrate a structure example of a semiconductor device.

FIGS. 3A to 3C illustrate structure examples of a semiconductor device.

FIGS. 4A to 4C illustrate structure examples of a semiconductor device.

FIGS. 5A1, 5A2, 5B1, 5B2, 5C1, 5C2, 5D1, and 5D2 each illustrate a structure example of a semiconductor device.

FIGS. 6A and 6B illustrate a structure example of a semiconductor device.

FIGS. 7A to 7C illustrate structure examples of a semiconductor device.

FIGS. 8A to 8C illustrate a structure examples of a semiconductor device.

FIGS. 9A to 9C illustrate a method for manufacturing a semiconductor device.

FIGS. 10A to 10C illustrate a method for manufacturing a semiconductor device.

FIG. 11 illustrates a structure example of a display device.

FIG. 12 illustrates a structure example of a display device.

FIG. 13 illustrates a structure example of a display device.

FIG. 14 illustrates a structure example of a display device.

FIG. 15 illustrates a structure example of a display device.

FIGS. 16A to 16F illustrate a method for manufacturing a display device.

FIGS. 17A to 17D illustrate structure examples of electronic devices.

FIGS. 18A to 18F illustrate structure examples of electronic devices.

FIGS. 19A to 19G illustrate examples of electronic devices.

FIG. 20A is an optical micrograph and FIG. 20B is a cross-sectional STEM image.

FIG. 21 shows measurement results of electrical characteristics of a transistor.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

The functions of a “source” and a “drain” are sometimes replaced with each other when a transistor of opposite polarity is used or when the direction of current flow is changed in circuit operation, for example. Thus, the terms “source” and “drain” can be used interchangeably in this specification.

In this specification and the like, the term “electrically connected” includes the case where components are connected through an “object having any electric function”. There is no particular limitation on an “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Note that in this specification and the like, the expression “having substantially the same top surface shapes” means that at least outlines of stacked layers partly overlap each other. For example, the case of patterning or partly patterning an upper layer and a lower layer with the use of the same mask pattern is included in the expression. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, a top surface shape of a component means the outline of the component in the plan view. A plan view means that the component is observed from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (formation order) of a stacked body or the like, even in the case where a surface on which the stacked body is provided (e.g., a formation surface, a support surface, a bonding surface, or a planarization surface) is located over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

In this specification and the like, a display panel that is one embodiment of a display device has a function of displaying (outputting) an image or the like on (to) a display surface. Thus, the display panel is one embodiment of an output device.

In this specification and the like, a structure in which a connector such as a flexible printed circuit (FPC) or a tape carrier package (TCP) is attached to a substrate of a display panel, or a structure in which an integrated circuit (IC) is mounted on a substrate by a chip on glass (COG) method or the like is referred to as a display panel module or a display module, or simply referred to as a display panel or the like in some cases.

### Embodiment 1

In this embodiment, a transistor of one embodiment of the present invention and a manufacturing method example of the transistor are described.

The transistor of one embodiment of the present invention includes a semiconductor layer, a gate insulating layer, a gate electrode, a first electrode, and a second electrode. The first electrode serves as one of a source electrode and a drain electrode, and the second electrode serves as the other of the source electrode and the drain electrode.

The second electrode is provided above the first electrode. Between the first electrode and the second electrode, an interlayer insulating layer (also referred to as a spacer) is provided. An opening reaching the first electrode is provided in the spacer, and the semiconductor layer is provided in contact with the first electrode, the second electrode, and a side wall (also referred to as a side surface) of the insulating layer in the opening. The gate insulating layer and the gate electrode are provided to cover the semiconductor layer located in the opening.

In the transistor having the above structure, the source electrode and the drain electrode are located at different heights, so that current flows in the semiconductor in the height direction. In other words, the channel length direction can be regarded as having a component of the height direction (the vertical direction); accordingly, the transistor of one embodiment of the present invention can be referred to as a vertical field-effect transistor (VFET), a vertical transistor, a vertical-channel transistor, and the like. In the transistor, the source electrode, the semiconductor, and the drain electrode can be provided to overlap with each other. Thus, the area occupied by the transistor can be significantly smaller than the area occupied by a so-called planar transistor (can also be referred to as a lateral transistor, (lateral FET, LFET)) in which a semiconductor is provided over a flat surface.

Since the area occupied by the above-described vertical transistor can be reduced, a display device including the vertical transistor can achieve a smaller pixel and a higher aperture ratio than a display device including a conventional lateral transistor, for example. In addition, more transistors can be provided in each pixel without increasing the area of the pixel, leading to multi-functionalization of pixels. Accordingly, the display device can achieve higher resolution, higher reliability, lower power consumption, and the like than a conventional display device.

The semiconductor layer preferably includes a metal oxide exhibiting semiconductor characteristics (also referred to as an oxide semiconductor). Since an oxide semiconductor has features such as higher mobility than that of amorphous silicon and higher productivity than that of crystalline silicon (e.g., polycrystalline silicon and single crystal silicon), the use of an oxide semiconductor can provide a high-performance and low-cost display device.

A channel formation region is provided in a part of the semiconductor layer that is in contact with the insulating layer serving as a spacer. In the channel formation region of the semiconductor layer, oxygen vacancies are preferably sufficiently reduced to enable a transistor to have favorable electrical characteristics. Thus, an oxide insulating film that releases oxygen by heating is preferably used as the insulating layer serving as a spacer. In that case, oxygen released from the insulating layer by heat in the manufacturing process of the transistor is supplied to the semiconductor layer, whereby oxygen vacancies in the channel formation region of the semiconductor layer can be reduced. Consequently, the transistor can have favorable normally-off electrical characteristics.

The insulating layer preferably has a stacked-layer structure of an oxide insulating film that releases oxygen by heating and a barrier insulating film having a barrier property against oxygen over the oxide insulating film. This structure can prevent release of oxygen included in the oxide insulating film from its top surface to the outside by heat in the process and the resulting lack of oxygen supply to the semiconductor layer.

As a larger amount of oxygen is included in the insulating layer, the amount of oxygen supplied to the semiconductor layer can be increased. Meanwhile, if the amount of oxygen included in the insulating layer is too large, excess oxygen present between the semiconductor layer and the insulating layer sometimes degrades the reliability of the transistor. Specifically, electric charge accumulating at the interface between the semiconductor layer and the insulating layer sometimes varies the electrical characteristics of the transistor. Hence, the insulating layer preferably includes an adequate amount of oxygen.

In view of the above, a degassing portion, through which oxygen from the insulating layer is released to the outside in the process, is provided in the periphery of the opening where the transistor is provided. Specifically, an opening is provided in a part of the barrier insulating film included in the insulating layer. Thus, by heat in the process or the like, oxygen in the oxide insulating film included in the insulating layer is partly released to the outside through the degassing portion, which can make the amount of oxygen in the oxide insulating film become adequate; oxygen can be prevented from remaining at the interface between the semiconductor layer and the insulating layer while an adequate amount of oxygen is supplied to the semiconductor layer. Consequently, the transistor can have favorable electrical characteristics and high reliability.

More specific examples will be described below with reference to drawings.

### Structure Example

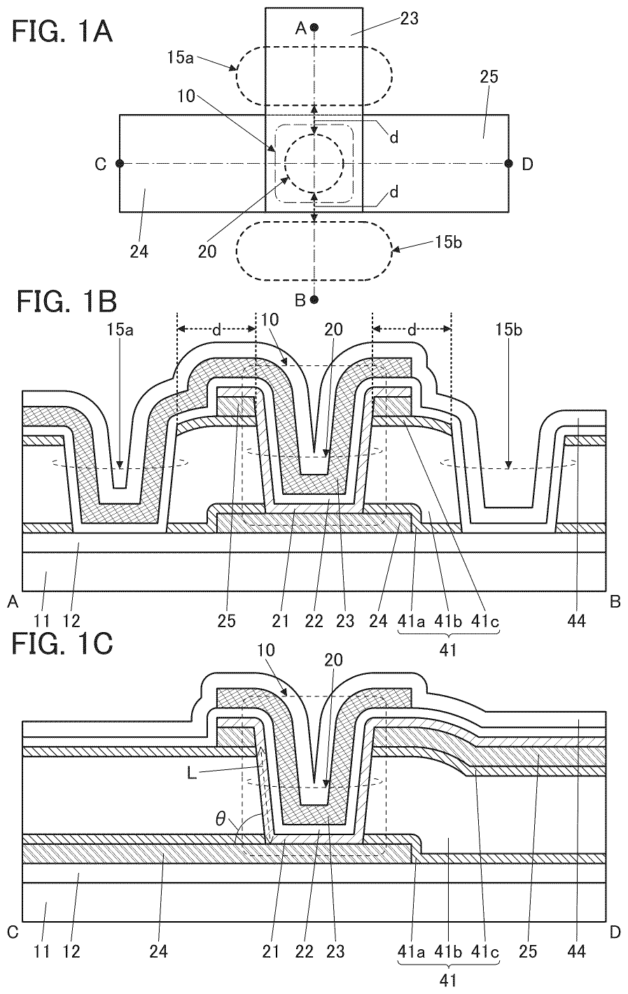

FIG. 1A is a plan view of a structure of a transistor 10 and its periphery. FIG. 1B is a schematic cross-sectional view taken along line A-B in FIG. 1A, and FIG. 1C is a schematic cross-sectional view taken along line C-D in FIG. 1A. Note that some components (e.g., insulating layers) are omitted in FIG. 1A.

The transistor 10 is provided over an insulating layer 12 provided over a substrate 11. The insulating layer 12 serves as a base insulating layer. The transistor 10 includes a semiconductor layer 21, an insulating layer 22 partly serving as a gate insulating layer, a conductive layer 23 partly serving as a gate electrode, a conductive layer 24 partly serving as one of a source electrode and a drain electrode, and a conductive layer 25 partly serving as the other of the source electrode and the drain electrode.

The conductive layer 24 is provided over the insulating layer 12, and an insulating layer 41 is provided over the conductive layer 24. The conductive layer 25 is provided over the conductive layer 41. The insulating layer 41 has an opening 20 reaching the conductive layer 24. In this example, an opening overlapping with the opening 20 is also provided in the conductive layer 25. Note that the conductive layer 25 does not necessarily include the opening, and the opening can be provided in the vicinity of the opening 20 located over the insulating layer 41.

The insulating layer 41 serves as a spacer insulating the conductive layer 24 from the conductive layer 25. The insulating layer 41 has a structure of three stacked layers, an insulating layer 41a, an insulating layer 41b, and an insulating layer 41c, in order starting from the insulating layer 12. The top surface of the conductive layer 24 is in contact with the insulating layer 41a. The conductive layer 25 is provided over the insulating layer 41c. The insulating layers 41a, 41b, and 41c can each be referred to as an insulating film.

The semiconductor layer 21 includes, in the opening 20 and the vicinity thereof, a part in contact with the top surface of the conductive layer 25, a part in contact with the side surface of the conductive layer 25, a part in contact with the side surface of the insulating layer 41c, a part in contact with the side surface of the insulating layer 41b, a part in contact with the side surface of the insulating layer 41a, and a part in contact with the top surface of the conductive layer 24.

The insulating layer 22 is provided to cover the insulating layer 41, the conductive layer 25, the semiconductor layer 21, and the conductive layer 24. With regard to the opening 20, the insulating layer 22 is provided along the concave top surface of the semiconductor layer 21.

The conductive layer 23 is provided to cover the insulating layer 22. With regard to the opening 20, the conductive layer 23 is provided along the concave top surface of the insulating layer 22.

The insulating layer 41 includes an opening 15a and an opening 15b in positions different from the position of the opening 20. The opening 15a includes a region overlapping with the conductive layer 23 in a plan view. The opening 15b is provided in a region overlapping with none of the conductive layers 23, 24, and 25 in the plan view.

The openings 15a and 15b are provided to penetrate the insulating layers 41a, 41b, and 41c to reach the insulating layer 12. Inside each of the openings 15a and 15b, the insulating layer 22 is provided in contact with the side surfaces of the insulating layers 41a, 41b, and 41c and the top surface of the insulating layer 12. The conductive layer 23 includes a part located inside the opening 15a.

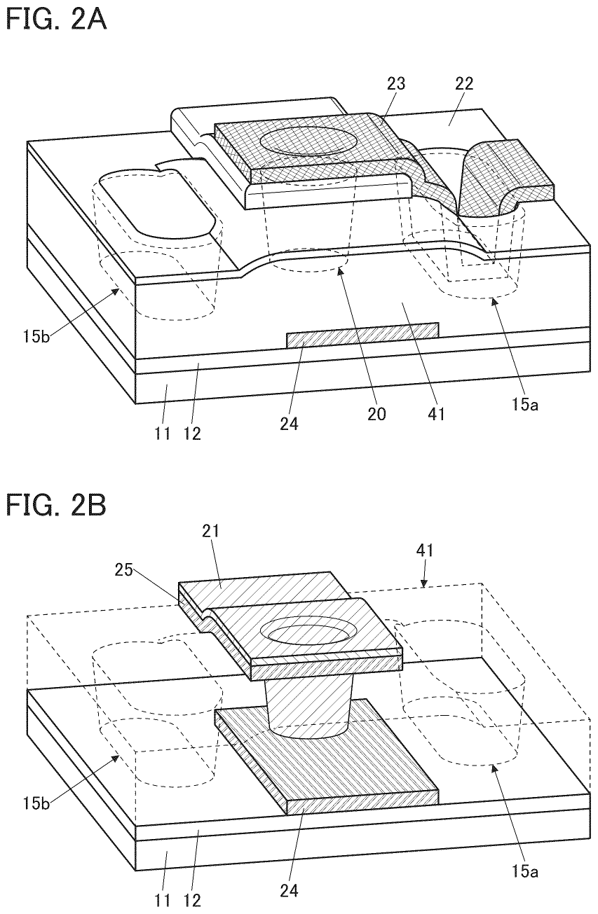

FIG. 2A is a schematic perspective view of the structure of the transistor 10 and its periphery. In FIG. 2A, the outlines of the openings 15a and 15b are indicated by dashed lines. FIG. 2B is a schematic perspective view illustrating the outline of the insulating layer 41 indicated by a dashed line, where the insulating layer 22 and the conductive layer 23 in FIG. 2A are omitted. As illustrated in FIG. 2A, the conductive layer 23 includes a part stuck in the depressed part of the opening 15a.

Here, the channel length of the transistor 10 can be precisely adjusted by the thickness of the insulating layer 41; therefore, a variation in the channel length can be extremely smaller than that of a planar transistor. Furthermore, by reducing the thickness of the insulating layer 41, a transistor with an extremely short channel length can be manufactured. For example, it is possible to manufacture a transistor with a channel length of 2 μm or shorter, 1 μm or shorter, 500 nm or shorter, 300 nm or shorter, 200 nm or shorter, 100 nm or shorter, 50 nm or shorter, 30 nm or shorter, or 20 nm or shorter and 5 nm or longer, 7 nm or longer, or 10 nm or longer. Thus, it is possible to achieve a transistor with an extremely short channel length that could not be achieved with a conventional light-exposure apparatus for mass production of flat panel displays (the minimum line width: approximately 2 μm or approximately 1.5 μm, for example). Moreover, a transistor with a channel length shorter than 10 nm can also be achieved without using an extremely expensive light-exposure apparatus used in the latest LSI technology.

A variety of semiconductor materials can be used for the semiconductor layer 21; in particular, an oxide semiconductor including a metal oxide is preferably used. The use of an oxide semiconductor formed under an appropriate condition allows a transistor having both a high on-state current and an extremely low off-state current to be achieved at a low cost. Described below are preferable structure examples of the case where an oxide semiconductor is used for the semiconductor layer 21 unless otherwise specified.

The top surfaces of the conductive layers 24 and 25 are in contact with the semiconductor layer 21. Hence, in the case where an oxide semiconductor is used for the semiconductor layer 21, the vicinities of the surfaces of the conductive layers 24 and 25 might be oxidized by the effect of heat or the like generated in a formation step of a semiconductor film to be the semiconductor layer 21 or a later step, so that an insulating oxide film might be formed between the conductive layer 24 or 25 and the semiconductor layer 21, increasing the contact resistance. Thus, an oxide conductor including a conductive oxide is preferably used at least for the uppermost part of the conductive layers 24 and 25. This can prevent an increase in the contact resistance due to the oxidation of the surfaces of the conductive layers 24 and 25. The conductive layers 24 and 25 can also be referred to as an oxide layer, a metal oxide layer, an oxide conductive layer, or the like.

The conductive layer 24 can be partly used as one of a source wiring and a drain wiring. The conductive layer 25 can be partly used as the other of the source wiring and the drain wiring. In the case where one or both of the conductive layers 24 and 25 are used as a wiring in this manner, they preferably have low electric resistance. Thus, a material having higher conductivity than an oxide conductor, such as a metal, an alloy, or a nitride thereof, is preferably used. One or both of the conductive layers 24 and 25 preferably have a stacked-layer structure including a layer of the material having high conductivity, where the above-described oxide conductor is preferably used at least for the uppermost part, in particular.

The transistor 10 is provided at the intersection of the conductive layer 23 serving as a gate wiring and the conductive layer 24 serving as the source wiring or the drain wiring. Accordingly, the area occupied by the transistor 10 can be extremely reduced.

The semiconductor layer 21 is provided in contact with the inner wall of the opening 20 in the insulating layer 41b. An oxide insulating film is preferably used as the insulating layer 41b. In particular, an oxide insulating film that releases oxygen by heating is preferably used. Furthermore, the insulating layer 41c having a barrier property against oxygen (an oxygen barrier property) is preferably provided over the insulating layer 41b. As the insulating layer 41c, a film through which oxygen is less likely to diffuse than through the insulating layer 41b (a film with a lower oxygen diffusion coefficient) is preferably used, for example. This can prevent diffusion of most of oxygen included in the insulating layer 41b to the outside and the resulting lack of oxygen supplied to the semiconductor layer 21. Furthermore, the insulating layer 41b is preferably interposed between the insulating layers 41a and 41c having a barrier property against oxygen. This enables oxygen included in the insulating layer 41b to be enclosed in a region surrounded by the insulating layers 41a and 41c and the semiconductor layer 21 and prevents a reduction in oxygen caused by release from the insulating layer 41b in the process, so that oxygen can be supplied to the semiconductor layer 21 more efficiently.

Typical examples of the oxide insulating film that releases oxygen by heating include a silicon oxide film and a silicon oxynitride film.

As the insulating film having an oxygen barrier property, an oxide, a nitride, or an oxynitride such as silicon nitride, silicon nitride oxide, aluminum oxide, aluminum oxynitride, aluminum nitride, hafnium oxide, hafnium oxynitride, hafnium aluminate, yttrium oxide, yttrium oxynitride, gallium oxide, or gallium-zinc oxide is preferably used. In particular, silicon nitride and aluminum oxide are preferably used because they can be formed as films having a high oxygen barrier property at low cost.

A part of the semiconductor layer 21 that is in contact with the insulating layer 41b is a region where oxygen vacancies are reduced, i.e., an i-type region. The other part of the semiconductor layer 21 that is not in contact with the insulating layer 41b is preferably an n-type region including a large amount of carriers. For example, the part of the semiconductor layer 21 that is in contact with the insulating layer 41b can be referred to as a channel formation region and regions on the outer side of the channel formation region can be referred to as low-resistance regions (or a source region or a drain region).

The openings 15a and 15b provided in the insulating layer 41 are each located at a predetermined distance from the opening 20 in a plan view. The openings 15a and 15b enable excess oxygen included in the insulating layer 41b to be released to the outside in the process. Although an example in which the openings 15a and 15b penetrate the insulating layer 41 and reach the insulating layer 12 is shown here, one embodiment of the present invention is not limited thereto. The openings 15a and 15b are provided at least in the insulating layer 41c in the insulating layers 41.

The openings 15a and 15b are configured to make the amount of oxygen included in the insulating layer 41b adequate by allowing heat in the process or the like to release excess oxygen included in the insulating layer 41b to the outside. In FIGS. 1A and 1B, the shortest distance between the openings 15a and 20 and the shortest distance between the openings 15b and 20 in a plan view are each referred to as a distance d and indicated by an arrow. The distance d between the openings 15a and 20 and the distance d between the openings 15b and 20 are preferably substantially equal to each other. This can inhibit unevenness of the amount of oxygen included in the insulating layer 41b in the vicinity of the semiconductor layer 21.

The distance d between the opening 20 and each of the openings 15a and 15b is preferably shorter than the diffusion length (diffusion distance) of oxygen in the insulating layer 41b. In this case, excess oxygen included in the insulating layer 41b in the vicinity of the semiconductor layer 21 can be released to the outside through the openings 15a and 15b. The diffusion length of oxygen depends on the diffusion coefficient of oxygen in the insulating layer 41b and the temperature and treatment time of heat treatment in the process. Hence, in accordance with the film quality of the insulating layer 41b and the temperature and treatment time of heat treatment in the manufacturing process, the openings 15a and 15b can be placed at an appropriate distance d from the opening 20 in order that an adequate amount of oxygen be released to the outside.

A diffusion coefficient with respect to a predetermined element of a thin film significantly depends not only on a formation method of a thin film but also on formation conditions of a thin film in some cases. For example, the diffusion coefficient of oxygen tends to depend on the ratio between the flow rate of a deposition gas (e.g., a silane gas) and deposition power when a silicon oxide film is formed by a plasma-enhanced chemical vapor deposition (PECVD) method. As the ratio of deposition power P to the flow rate S of a silane gas (P/S) is lower, a film with a higher diffusion coefficient can be obtained. Such a difference in diffusion coefficient can be confirmed as a difference in wet etching rate, for example.

The distance d between the opening 20 and each of the openings 15a and 15b can be an adequate distance depending on the film quality of the insulating layer 41b and the manufacturing process of the transistor, and can be, for example, greater than or equal to the minimum feature size and less than or equal to 100 μm, such as greater than or equal to 0.1 μm and less than or equal to 100 μm, preferably greater than or equal to 0.1 μm and less than or equal to 50 μm, further preferably greater than or equal to 0.1 (m and less than or equal to 30 (m, still further preferably greater than or equal to 0.1 μm and less than or equal to 20 μm. Note that in the case where the minimum feature size can be less than 0.1 μm, the distance d can be reduced to greater than or equal to 10 nm and less than or equal to 50 nm or even to greater than or equal to 10 nm and less than or equal to 30 nm.

Here, the channel length and channel width of the transistor 10 and the like are described.

A channel length L of the transistor 10 can be defined as, as illustrated in FIG. 1C, the length of a part of the semiconductor layer 21 that is in contact with the insulating layer 41 on the shortest path connecting a part in contact with the conductive layer 24 and a part in contact with the conductive layer 25. Note that the channel length L can be defined as the length of a part in contact with the insulating layer 41b in the case where a part other than the part in contact with the insulating layer 41b (i.e., the parts in contact with the insulating layers 41a and 41c) can be regarded as having low resistance. When the opening 20 in the insulating layer 41 has a sidewall angle (I) less than 90°, i.e., the insulating layer 41 has a tapered shape, the channel length L can be increased to exceed (made larger than) the thickness of the insulating layer 41 (or the insulating layer 41b).

A channel width W (not illustrated) of the transistor 10 depends on the shape of the opening 20. When the outline of the opening 20 is a circle with a diameter R, the channel width W can be regarded as the circumference of the opening 20 (i.e., Ξ×R). Here, the perimeter of the opening 20 varies with the height if the sidewall angle I of the opening 20 in the insulating layer 41 shifts from 90°. In that case, the channel width W can be regarded as the perimeter of the opening 20 with the minimum diameter (at the lower end here). The channel width W can also be regarded as the perimeter of the opening 20 at the upper end or at a middle portion.

The shape of the opening 20 in a plan view can be typically a circular shape. However, the shape of the opening 20 is not limited to a circular shape and can be a variety of shapes. Besides the circular shape, for example, an elliptical shape or a quadrangular shape with rounded corners can be employed. Alternatively, a regular polygonal shape such as a regular triangular shape, a square shape, or a regular pentagonal shape or a polygonal shape other than the regular polygonal shape can be employed. By employing a depressed polygonal shape in which at least one interior angle is greater than 180°, such as a star polygonal shape, the channel width can be increased. Alternatively, a quadrangular shape with rounded corners, a closed curve in which a straight line and a curve are combined, or the like can be employed.

Since the semiconductor layer 21 and the insulating layer 22 are formed along the inner wall of the opening 20 in the insulating layer 41, the thicknesses of the layers are sometimes reduced in the opening 20 by some film formation methods. For example, when a film formation method such as a sputtering method or a plasma CVD method is used, a film formed on a surface inclined with respect to the substrate surface or a surface perpendicular to the substrate surface tends to be thinner than a film formed on a surface parallel to the substrate surface. By contrast, a film formation method such as an atomic layer deposition (ALD) method or a thermal CVD method allows a film with a uniform thickness to be formed on a surface with any angle. The semiconductor layer 21 and the insulating layer 22 are preferably formed by an ALD method when the opening 20 in the insulating layer 41 has a sidewall angle I of 750 or more, 80° or more, or 85° or more, for example.

### [Components]

### <Substrate>

As the substrate 11 over which the transistor is formed, for example, an insulator substrate, a semiconductor substrate, or a conductor substrate can be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, gallium oxide, or gallium nitride. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements can be used. Examples of the elements provided over the substrates include a capacitor, a resistor, a switching element (such as a transistor), a light-emitting element, and a memory element.

### <Semiconductor Layer>

The semiconductor layer 21 preferably includes a metal oxide (an oxide semiconductor).

Examples of the metal oxide that can be used for the semiconductor layer 21 include an In oxide, a Ga oxide, and a Zn oxide. The metal oxide preferably includes at least In, Zn, Sn, or Al or further preferably includes In or Zn.

The metal oxide preferably includes two or three elements selected from In, an element M, and Zn. For example, In-M-Zn oxide, In-M oxide, or M-Zn oxide can be used. The element M is a metal element or metalloid element that has a high bonding energy with oxygen, such as a metal element or metalloid element whose bonding energy with oxygen is higher than that of In. Examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The metal oxide preferably includes one or more kinds selected from the above elements, and particularly preferably includes one or more kinds selected from Al, Ga, Y, and Sn. In this specification and the like, a “metal element” may refer to a metalloid element.

The proportion of the number of In atoms is preferably higher than or equal to the number of element M atoms in the In-M-Zn oxide. By increasing the proportion of the number of In atoms in the metal oxide, the on-state current, field-effect mobility, or the like of the transistor can be improved. Examples of the atomic ratio of the metal elements of such In-M-Zn oxide, In-M-Zn, include 1:1:1, 1:1:1.2, 2:1:3, 3:1:2, 4:2:3, 4:2:4.1, 5:1:3, and 5:1:6 and a composition in the vicinity of any of the above atomic ratios. Note that the neighborhood of the atomic ratio includes ±30% of an intended atomic ratio.

The proportion of the number of In atoms can also be lower than that of the number of element M atoms in the In-M-Zn oxide. By increasing the proportion of the number of element M atoms in the metal oxide, generation of oxygen vacancies can be inhibited. Examples of the atomic ratio of the metal elements of the In-M-Zn oxide, In-M-Zn, include 1:3:2, 1:3:3, and 1:3:4 and a composition in the vicinity of any of the above atomic ratios.

For the semiconductor layer 21, for example, In oxide, In—Zn oxide, In—Ga oxide, In—Sn oxide, In—Ti oxide, In—W oxide, In—Ga—Al oxide, In—Ga—Sn oxide, In—Ga—Zn oxide, In—Sn—Zn oxide, In—Al—Zn oxide, In—Ti—Zn oxide, In—W—Zn oxide, In—Ga—Sn—Zn oxide, or In—Ga—Al—Zn oxide can be used. As the oxide that does not contain In, Ga oxide, Zn oxide, Ga—Zn oxide, Ga—Sn oxide, Al—Zn oxide, Al—Sn oxide, or the like can also be used. A material that does not contain Zn like indium oxide is preferred in that it improves the compatibility with an LSI manufacturing process. By contrast, a material that contains Zn is preferred in that crystallinity can be easily increased.

Note that the metal oxide can contain a metal element having a relatively large atomic number instead of or in addition to indium. As the overlap between orbits of metal elements is larger, the metal oxide tends to have higher carrier conductivity. Thus, a transistor including a metal element having a relatively large atomic number can have high field-effect mobility in some cases. For example, one or more of metal elements belonging to Period 5 and metal elements belonging to Period 6 can be used. Specific examples of the metal element include Y, Zr, Ag, Cd, Sn, Sb, Ba, Pb, Bi, La, Ce, Pr, Nd, Pm, Sm, and Eu.

The metal oxide can contain one or more selected of nonmetallic elements. A transistor including the metal oxide including a nonmetallic element can have high field-effect mobility in some cases. Examples of the nonmetallic element include C, N, P, S, Se, F, Cl, Br, and H.

A sputtering method or an atomic layer deposition (ALD) method can be suitably used to form the metal oxide. A sputtering method is preferably used because the impurity concentration can be reduced. An ALD method is preferably used because the coverage can be improved. Note that in the case where the metal oxide is formed by a sputtering method, the atomic ratio of the deposited metal oxide may be different from the atomic ratio of a target. In particular, the zinc content of the deposited metal oxide may be reduced to approximately 50% of that of the target.

In this specification and the like, the content of a certain metal element in a metal oxide refers to the proportion of the number of atoms of the metal element to the total number of metal element atoms contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by Aₓ/(A_{X}+A_{Y}+A_{Z}). Moreover, in the case where the atomic ratio of the metal element X to the metal element Y and the metal element Z contained in the metal oxide is represented by B_{X}:B_{Y}:B_{Z}, the content of the metal element X can be represented by B_{X}/(B_{X}+B_{Y}+B_{Z}).

In the case of using a metal oxide containing In, for example, an increase in the In content enables a transistor to have a high on-state current.

When the semiconductor layer 21 includes a metal oxide not containing Ga or having a low Ga content, a transistor can have high reliability against positive bias application. That is, the transistor can show a small amount of change in the threshold voltage in the positive bias temperature stress (PBTS) test. In the case of using a metal oxide containing Ga, the Ga content is preferably lower than the In content. Accordingly, the transistor can have high mobility and high reliability.

Meanwhile, a transistor having a high Ga content can have high reliability against light. That is, the transistor can show a small amount of change in the threshold voltage of the transistor in the negative bias temperature illumination stress (NBTIS) test. Specifically, a metal oxide in which the proportion of the number of Ga atoms is greater than or equal to that of the number of In atoms has a wider band gap and can reduce the amount of change in the threshold voltage of the transistor in the NBTIS test.

Furthermore, a metal oxide having a high zinc content has high crystallinity whereby diffusion of impurities can be inhibited. Consequently, a change in electrical characteristics of the transistor is suppressed and the transistor can have high reliability.

The semiconductor layer 21 can have a stacked-layer structure including two or more metal oxides. The two or more metal oxides included in the semiconductor layer 21 can have the same composition or substantially the same compositions. Employing a stacked-layer structure of metal oxides having the same composition can reduce the manufacturing cost because the metal oxide layers can be formed using the same sputtering target. Note that a stacked-layer structure including two or more oxides having different compositions can be employed. The use of an ALD method can form a metal oxide with a composition that continuously changes in the thickness direction. This not only increases the range of choices for design without need for use of a film with a predetermined composition but also prevents generation of an interface state or the like between two layers with different compositions; thus, the electrical characteristics and reliability can be improved.

In the case where the semiconductor layer 21 has a two-layer structure, the second layer, i.e., the layer closer to the gate electrode, preferably includes a material with higher mobility (higher conductivity) than the first layer. This structure enables the transistor to have normally-off characteristics and a high on-state current. Consequently, both low power consumption and high performance can be achieved. Alternatively, the first layer, i.e., the layer in contact with the source electrode and the drain electrode, can include a material having higher mobility than the second layer. In that case, the contact resistance between the semiconductor layer 21 and the source electrode or the drain electrode can be reduced and the parasitic resistance can be reduced accordingly, so that the transistor can have a high on-state current.

In the case where the semiconductor layer 21 has a three-layer structure, the second layer preferably includes a material having higher mobility than the first layer and the third layer. This structure enables the transistor to have normally-off characteristics and high reliability.

The mobility and the conductivity are improved with the higher content of an element that contributes to an increase in conductivity, such as indium. Examples of a high mobility material include materials having an atomic ratio of In:Ga:Zn=4:3:2, In:Zn=1:1, In:Zn=2:1, In:Zn=4:1, In:Sn:Zn=40:1:10, In:Sn:Zn=20:1:10, In:Sn=95:5, and In:Sn=90:10 and materials having an atomic ratio in the vicinity of any of the above atomic ratios. Examples of a material having lower mobility than the above-described materials include materials with In:Ga:Zn atomic ratios of 1:3:2, 1:3:4, 2:2:1, 1:1:1, and 1:1:2 and materials having an atomic ratio in the vicinity of any of the above atomic ratios.

It is preferable to use a metal oxide layer having crystallinity as the semiconductor layer 21. For example, a metal oxide layer having a c-axis aligned crystal (CAAC) structure, a polycrystalline structure, a nano-crystal (nc) structure, or the like can be used. By using a metal oxide layer having crystallinity as the semiconductor layer 21, the density of defect states in the semiconductor layer 21 can be reduced, which enables the semiconductor device to have high reliability.

As the crystallinity of the metal oxide layer used as the semiconductor layer 21 becomes higher, the density of defect states in the semiconductor layer 21 can be reduced. By contrast, the use of a metal oxide layer having low crystallinity enables a transistor to flow large current.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (the leakage current is hereinafter also referred to as an off-state current), and charge accumulated in a capacitor that is connected in series to the transistor can be held for a long period. Furthermore, the power consumption of the semiconductor device can be reduced with the OS transistor.

The semiconductor device of one embodiment of the present invention can be used for a display device, for example. To increase the emission luminance of a light-emitting device included in a pixel circuit of a display device, it is necessary to increase the amount of current flowing through the light-emitting device. For this, it is necessary to increase the source-drain voltage of a driving transistor included in the pixel circuit. Since an OS transistor has a higher breakdown voltage between the source and the drain than a transistor including silicon (hereinafter referred to as a Si transistor), a high voltage can be applied between the source and the drain of the OS transistor. Thus, with the use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Accordingly, the gray level in the pixel circuit can be increased. Moreover, a stable current can flow through the light-emitting device even when the electrical characteristics (e.g., resistance) of the light-emitting device change or the electrical characteristics of the light-emitting devices vary.

As described above, with use of an OS transistor as a driving transistor included in the pixel circuit, it is possible to achieve “inhibition of black floating”, “increase in emission luminance”, “increase in gray level”, “reduction in influence of manufacturing variation in light-emitting devices”, and the like.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that a semiconductor material that can be used for the semiconductor layer 21 is not limited to an oxide semiconductor. For example, a single-element semiconductor or a compound semiconductor can be used. Examples of the single-element semiconductor include Si (such as single crystal Si, polycrystalline Si, microcrystalline Si, and amorphous Si) and Ge. Examples of the compound semiconductor include GaAs and SiGe. Examples of the compound semiconductor include an organic semiconductor, a nitride semiconductor, and an oxide semiconductor. These semiconductor materials can contain impurities as dopants.

Alternatively, for the semiconductor layer 21, a material having a layered crystal structure can be used. A material having a layered crystal structure has high electrical conductivity in a plane of the layer. Thus, when such a material having a layered crystal structure is used for a channel formation region, the transistor can have a high on-state current. Examples of the material include graphene, silicane, and chalcogenide. Examples of chalcogenide include chalcogenide of transition elements such as Mo, W, Hf, and Zr. Examples of chalcogen elements include Group 16 elements such as S, Se, and Te.

There is no particular limitation on the crystallinity of a semiconductor material used for the semiconductor layer 21, and any of an amorphous semiconductor, a single crystal semiconductor, and a semiconductor having other crystallinity than single crystal (a polycrystalline semiconductor, a microcrystalline semiconductor, or a semiconductor partly including crystal regions) can be used. It is preferable to use a semiconductor having crystallinity, in which case deterioration of the transistor characteristics can be suppressed.

### <Gate Insulating Layer>

The insulating layer 22 functions as a gate insulating layer of the transistor and can also be used as a dielectric layer of the capacitor. In the case where the semiconductor layer 21 is formed using an oxide semiconductor, an oxide insulating film is preferably used for at least a part of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 can have a stacked-layer structure, e.g., a stacked-layer structure including at least one oxide insulating film and at least one nitride insulating film.

Note that in this specification and the like, oxynitride refers to a material that contains more oxygen than nitrogen. Nitride oxide refers to a material that contains more nitrogen than oxygen.

The insulating layer 22 preferably has a stacked-layer structure using an insulating material that includes a high-k material. A stacked-layer structure including a high dielectric constant (high-k) material and a material having higher dielectric strength than the high-k material is preferably used. For example, as the insulating layer 22, an insulating film (also referred to as ZAZ) in which zirconium oxide, aluminum oxide, and zirconium oxide are stacked in this order can be used. An insulating film (also referred to as ZAZA) in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor.

A material that exhibits ferroelectricity can be used for the insulating layer 22. Examples of the material that exhibits ferroelectricity include metal oxides such as hafnium oxide, zirconium oxide, and HfZrO_{X} (X is a real number greater than 0).

### <Conductive Layer>

The conductive layers 24 and 25 are in contact with the semiconductor layer 21. Here, when the semiconductor layer 21 is formed using an oxide semiconductor and a part of the conductive layer 24 or the conductive layer 25 in contact with the semiconductor layer 21 is formed using, for example, a metal that is likely to be oxidized such as aluminum, an insulating oxide (e.g., aluminum oxide) is formed between the conductive layer 24 or 25 and the semiconductor layer 21, which might inhibit electrical continuity between the conductive layer and the semiconductor layer. Therefore, at least a part of the conductive layer 24 or the conductive layer 25 in contact with the semiconductor layer 21 is preferably formed using a conductive material that is less likely to be oxidized, a conductive material that maintains low electric resistance even when oxidized, or an oxide conductive material.

For the conductive layers 24 and 25, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide. A conductive oxide containing indium is particularly preferable because of its high conductivity. Alternatively, the above-described oxide material such as In—Ga—Zn oxide that can be used for the semiconductor layer 21 can be used for the conductive layer when the carrier concentration is increased.

For the conductive layers 24 and 25, any of the following structures can be used: a single-layer structure of the above conductive oxide film, a three-layer structure in which a titanium nitride film, a tungsten film, and a titanium nitride are stacked in this order, a two-layer structure in which a ruthenium film or a ruthenium oxide film is stacked over a tungsten film, a two-layer structure in which a ruthenium film or a ruthenium oxide film is stacked over the above conductive oxide film, a two-layer structure in which the above conductive oxide film is stacked over a ruthenium film or a ruthenium oxide film, or the like, for example. Note that ruthenium is a material that is not easily etched and thus is preferably as thin as possible when used; ruthenium used preferably has a thickness greater than or equal to 0.1 nm and less than or equal to 2 nm, for example.

The conductive layer 23 serves as a gate electrode and can be formed using a variety of conductive materials. For the conductive layer 23, for example, a metal element selected from Al, Cr, Cu, Ag, Pt, Ta, Ni, Ti, Mo, W, Hf, V, Nb, Mn, Mg, Zr, Be, In, Ru, Ir, Sr, La, and the like or an alloy containing any of these metal elements as its component is preferably used. It is also possible to use a nitride or an oxide of any of the above metals or the alloy. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide can be used.

For the conductive layer 23, the nitride and the oxide that can be used for the conductive layers 24 and 25 can be used.

The conductive layers 23, 24, and 25 also serve as wirings and thus are preferably formed using stacked low-resistance conductive materials. For example, the above-described low-resistance conductive material that can be used for the conductive layer 23 can also be used for the lower layers in the conductive layers 24 and 25.

### <Insulating Layer>

The insulating layer 41b can be used as an interlayer insulating film. The insulating layer 41b is preferably formed by a film formation method such as a sputtering method or a plasma CVD method, for example. It is particularly preferable to employ a sputtering method, in which a hydrogen gas does not need to be used as a deposition gas, to form a film having an extremely low hydrogen content. Consequently, supply of hydrogen to the semiconductor layer 21 is inhibited and the electrical characteristics of the transistor 10 can be stabilized.

The insulating layer 41b is in contact with the channel formation region of the semiconductor layer 21 and therefore is preferably formed using an oxide insulating film. In particular, an oxide insulating film that releases oxygen by heating is preferably used. An oxide insulating film that can be used as the gate insulating layer can be used as the insulating layer 41b.

Since the insulating layer 41b serves as an interlayer insulating layer, it is preferably formed by a film formation method that enables a higher film formation rate than those of the other insulating layers. For example, a film of tetraethyl orthosilicate (TEOS) whose chemical formula is Si(OC₂H₅)₄, formed by a plasma CVD method can also be used for the insulating layer 41. The productivity can be thus increased.

For the insulating layers 41a and 41c, a material that is less likely to transmit oxygen than the material of the insulating layer 41b, i.e., has an oxygen barrier property, is preferably used. For the insulating layers 41a and 41b, the above insulating film having an oxygen barrier property can be used. In particular, silicon nitride or aluminum oxide is preferably used.

The insulating layer 41b and either of the insulating layers 41a and 41c can be formed using insulating films including the same element (e.g., silicon oxide). In this case, an insulating film having a higher density than the insulating layer 41b, e.g., an insulating film having a lower etching rate than the insulating layer 41b, can be used.

As the insulating layers 41a and 41c, films in which hydrogen is less likely to be diffused are preferably used. The layers 41a and 41c in which hydrogen is less likely to be diffused are provided above and below the insulating layer 41b, respectively, thereby preventing entry of hydrogen from the outside into the insulating layer 41b in contact with the semiconductor layer 21.

Silicon nitride and silicon nitride oxide are particularly suitable for the insulating layers 41a and 41c because they release fewer impurities (e.g., water and hydrogen) and are less likely to transmit oxygen and hydrogen.

The insulating layer 12 serves as a base insulating layer or an interlayer insulating layer. For the insulating layer 12, an insulating material that can be used for the insulating layer 41b or an insulating material that can be used for the insulating layers 41a and 41c can be used as appropriate.

The above is the description of the components.

### [Structure Examples of Openings]

Although FIG. 1A illustrates the case where the openings 15a and 15b each have a horizontally long shape in a plan view, the shapes of the openings 15a and 15b are not limited thereto. Examples different from the above are described below.

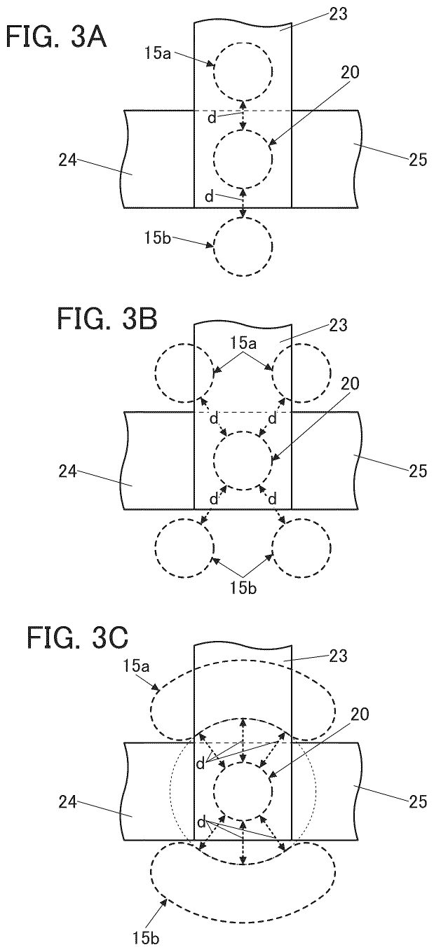

FIG. 3A illustrates an example in which the openings 15a and 15b each have a circular shape in a plan view. The openings 15a and 15b are each a circle with substantially the same diameter as the opening 20. The opening 15a in FIG. 3A is located within the conductive layer 23 in the plan view while the opening 15a in FIG. 1A includes a portion not overlapping with the conductive layer 23.

An example in which four openings are provided is shown in FIG. 3B. FIG. 3B illustrates two openings 15a and two openings 15b. Each of the two openings 15a partly overlaps with the conductive layer 23. Increasing the number of openings in this manner enables more efficient release of oxygen from the insulating layer 41b. The structure in this example has the effect of shortening the treatment time or lowering the treatment temperature in the case of performing heat treatment for release of oxygen, for example.

FIG. 3C illustrates an example in which the openings 15a and 15b illustrated as an example in FIG. 1A each have a curved shape. The outline of each of the openings 15a and 15b illustrated in FIG. 3C includes parts whose shortest distances from the opening 20 are equal. In the case where the opening 20 has a circular shape, there are parts where the outlines of the openings 15a and 15b partly overlap with a concentric circle (indicated by the dashed line) around the center of the opening 20, for example. Thus, in each of the openings 15a and 15b, as the region whose shortest distances from the opening 20 are equal is larger, oxygen from the insulating layer 41b can be released more efficiently.

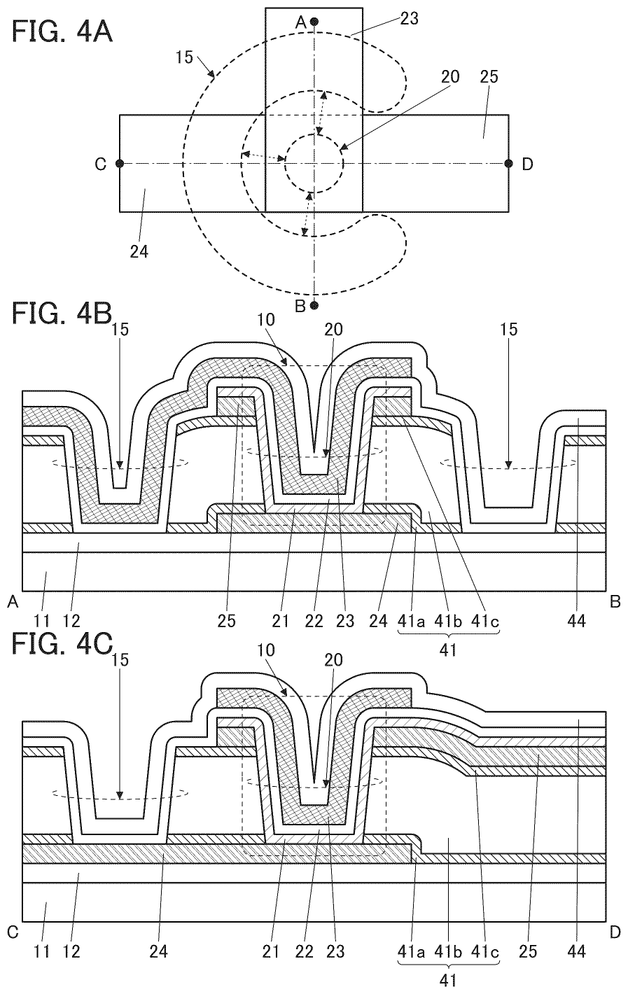

Although the opening 15a overlapping with the conductive layer 23 is provided in the above example, an opening overlapping with the conductive layer 24 can be provided. FIG. 4A illustrates an example in which an opening 15 including a part overlapping with the conductive layer 23 and a part overlapping with the conductive layer 24 is provided. Here, an example in which part of the outline of the opening 15 overlaps with a concentric circle (indicated by the dashed line) around the center of the opening 20 is shown. The opening 15 covers an area at greater than or equal to 180° angle around the opening 20 in this manner, thereby enabling extremely efficient release of oxygen from the insulating layer 41b.

FIGS. 4B and 4C are schematic cross-sectional views. As illustrated in FIG. 4C, a part of the insulating layer 22 is in contact with the top surface of the conductive layer 24 through the opening 15 in a region where the opening 15 and the conductive layer 24 overlap with each other.

Note that the arrangement of the openings 15, 15a, and 15b described here is just an example, and the openings 15, 15a, and 15b can be arranged in various ways as long as they are not located in the region overlapping with the conductive layer 25 in a plan view. In addition, there is no limitation on the number of openings, and the number of openings provided for one transistor can be one, three or five or more. The opening can be shared by two or more transistors. For example, one or more openings can be provided for two transistors, or one or more openings can be provided for three transistors.

### [Cross-Sectional Shape of Openings]

Next, examples of a cross-sectional shape of the opening 15a, 15b, or 15 which are different from the above are described. Since the number of openings is one or more as described above, the opening 15a, 15b, and 15 are collectively referred to as the opening 15 without being distinguished from one another in the following description.

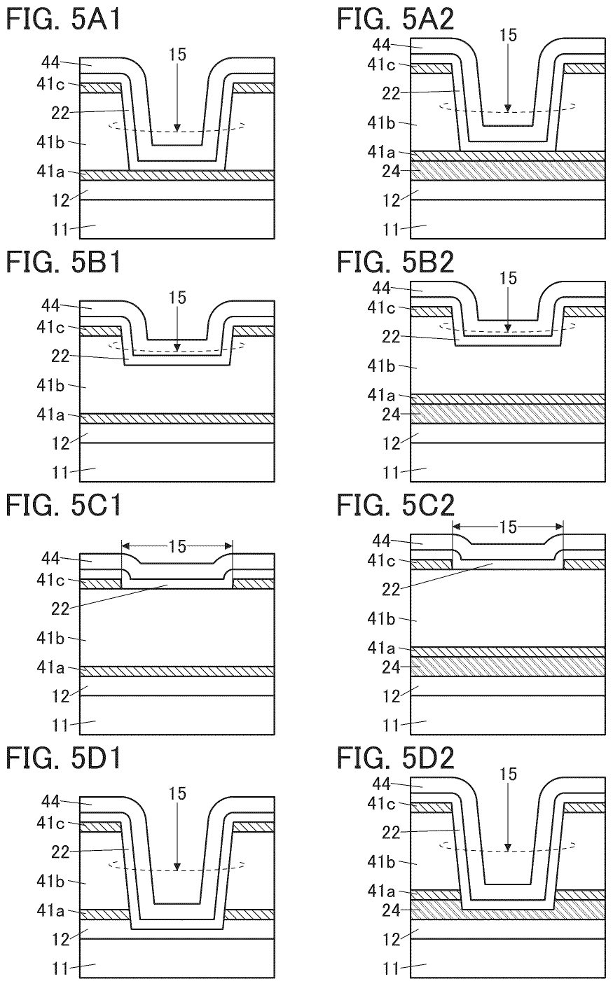

FIG. 5A1 is a schematic cross-sectional view of the opening 15 and the periphery. FIG. 5A2 illustrates an example in which the opening 15 overlaps with the conductive layer 24.

FIGS. 5A1 and 5A2 illustrate examples in which the opening 15 penetrates the insulating layers 41c and 41b of the insulating layer 41 and reaches the insulating layer 41a. In the opening 15, a part of the insulating layer 22 is provided in contact with the top surface of the insulating layer 41a. With such a structure, the insulating layer 41a can serve as an etching stopper at the time of etching for formation of the opening 15 and accordingly the controllability of the etching can be increased.

In FIGS. 5B1 and 5B2, the opening 15 is provided in the insulating layer 41c and a part of the insulating layer 41b of the insulating layer 41. In other words, a depression is formed in a part of the insulating layer 41b overlapping with the opening 15.

In FIGS. 5C1 and 5C2, the opening 15 is provided only in the insulating layer 41c of the insulating layer 41.

As described above, the opening 15 is provided in at least the insulating layer 41c of the insulating layer 41, and the insulating layer 41b and the insulating layer 22 are in contact with each other inside the opening 15. As the depth of the opening 15 is increased, the surface area of the insulating layer 41b in the opening 15 becomes larger; accordingly, oxygen can be efficiently released from the insulating layer 41b.

In the examples illustrated in FIGS. 5D1 and 5D2, the opening 15 penetrates the insulating layers 41c, 41b, and 41a and reaches a part of a layer having a surface where the insulating layer 41a is formed. In FIG. 5D1, a depression is provided in a part of the insulating layer 12 overlapping with the opening 15, and the depression is covered with the insulating layer 22. In FIG. 5D2, a depression is provided in a part of the insulating layer 24 overlapping with the opening 15, and the depression is covered with the insulating layer 22. In the case where the opening 15 penetrates the insulating layer 41a in this manner, the insulating layer 12 or the conductive layer 24 having the surface where the insulating layer 41a is formed may be partly etched depending on etching conditions of the insulating layer 41a.

### MODIFICATION EXAMPLES

Structure examples partly different from the above structure examples will be described below. Note that in some cases, the above description is referred to for the portions already described and repetitive description thereof will be omitted.

### Modification Example 1

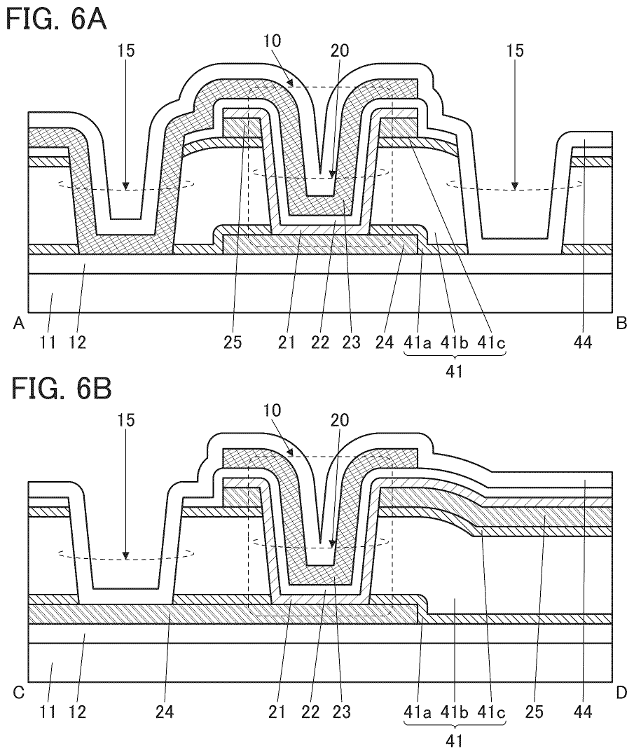

In FIGS. 6A and 6B, the opening 15 penetrates not only the insulating layer 41 but also the insulating layer 22. In a region of the opening 15 that does not overlap with the conductive layer 23, an insulating layer 44 is provided in contact with the side surfaces of the insulating layers 22, 41c, 41b, and 41a. In a region of the opening 15 that overlaps with neither the conductive layer 23 nor 24, the top surface of the insulating layer 12 is in contact with the insulating layer 44, as illustrated in FIG. 6A. In a region of the opening 15 that overlaps with the conductive layer 24, the top surface of the conductive layer 24 is in contact with the insulating layer 44, as illustrated in FIG. 6B.

In a region of the opening 15 that overlaps with the conductive layer 23, the conductive layer 23 is provided in contact with the side surfaces of the insulating layers 22, 41c, 41b, and 41a and the top surface of the insulating layer 12.

Such structures can be obtained by forming the openings 20 and 15 in different steps. Specifically, the opening 15 is formed in the insulating layers 22 and 41 after the formation of the insulating layer 22 but before the formation of the conductive layer 23. Note that in the case of not providing a region where the opening 15 and the conductive layer 23 overlap with each other, the opening 15 can be provided in a part not overlapping with the conductive layer 23 after the formation of the conductive layer 23 but before the formation of the insulating layer 44.

### Modification Example 2

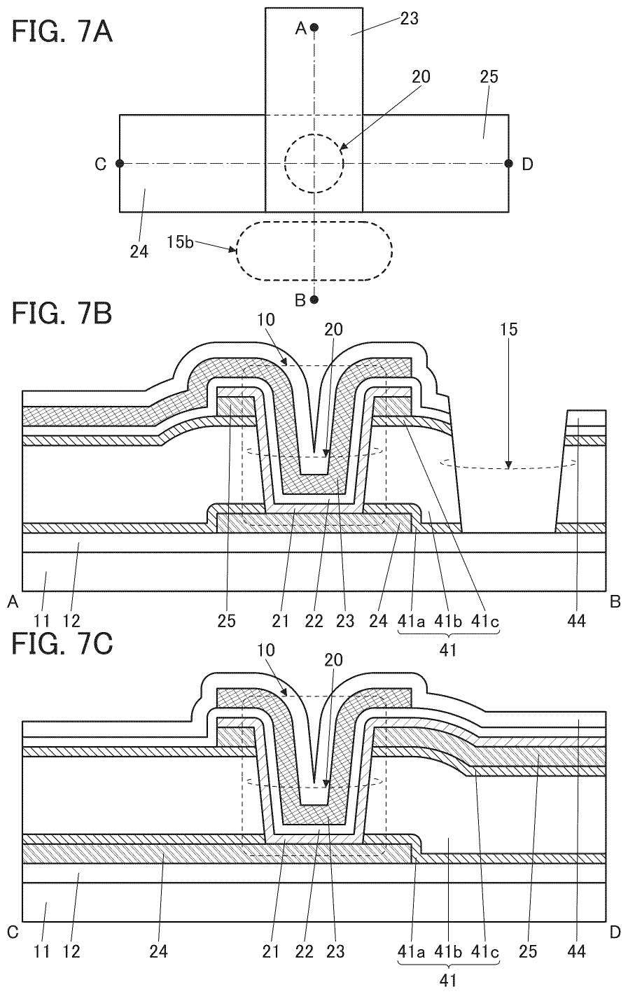

In FIGS. 7A, 7B, and 7C, the opening 15 penetrates not only the insulating layer 41 but also the insulating layers 44 and 22. In such an example, the opening 15 is preferably provided in a region overlapping with none of the conductive layers 23, 24, and 25. In the case where another insulating layer is provided over the insulating layer 44, the opening 15 can be provided at a position overlapping with the conductive layer 24.

### Modification Example 3

An example where a conductive layer serving as a back gate is provided is described below.

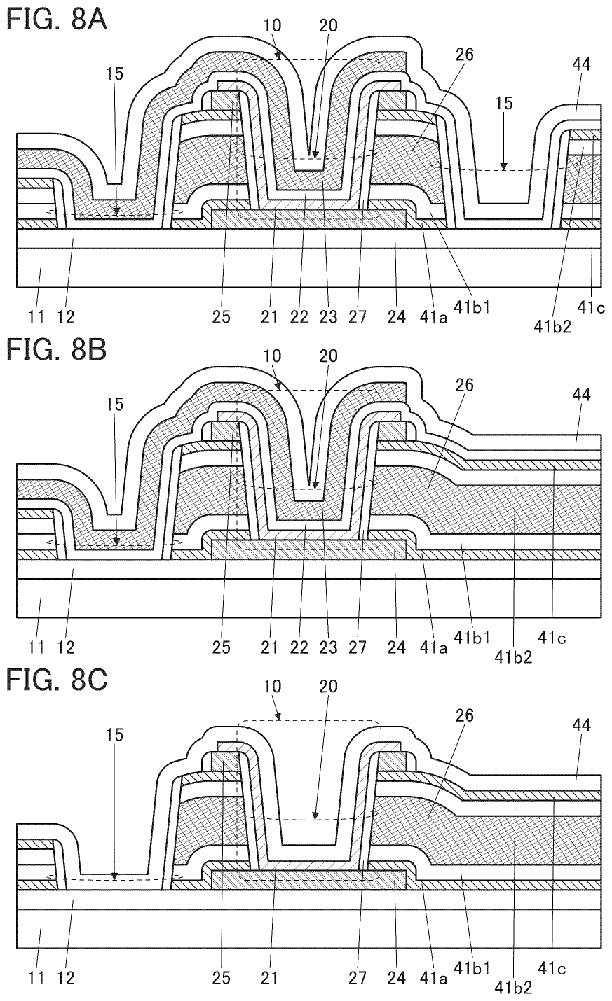

The structure illustrated in FIG. 8A is different from the above structure examples mainly in including a conductive layer 26 and an insulating layer 27.

The conductive layer 26 serves as a second gate electrode (or a back gate electrode). The insulating layer 27 is between the conductive layer 26 and the semiconductor layer 21 and serves as a second gate insulating layer (or a back gate insulating layer). A fixed potential or a given signal can be supplied to the conductive layer 26. By providing the conductive layer 26 and supplying an appropriate potential to the conductive layer 26, the threshold voltage of the transistor can be controlled. Furthermore, the potential of the back channel side of the semiconductor layer 21 can be fixed, so that variation in electrical characteristics can be reduced. The conductive layer 26 can also be supplied with the same potential or signal as any one of the conductive layers 24, 25, and 23.

Here, the example in which the insulating layer 41 has a four-layer structure of the insulating layer 41a, an insulating layer 41b1, an insulating layer 41b2, and the insulating layer 41c is described. The conductive layer 26 is provided between the insulating layers 41b1 and 41b2.

In the opening 20, the insulating layer 27 is provided in contact with the side surfaces of the insulating layer 41a, the insulating layer 41b1, the conductive layer 26, the insulating layer 41b2, the insulating layer 41c, and the conductive layer 25. In the opening 15, the insulating layer 27 is provided in contact with the insulating layer 41a, the insulating layer 41b1, the conductive layer 26, the insulating layer 41b2, and the insulating layer 41c. The insulating layer 27 is provided in contact with not only the side surface of the conductive layer 25 on the opening 20 side but also the opposite side surface of the conductive layer 25.

The insulating layer 27 can be formed by, for example, anisotropic etching after forming the openings 20 and 15 and then forming an insulating film covering the openings by a formation method providing high coverage. The insulating layer 27 can also be referred to as a sidewall insulating film.

The opening 15 illustrated on the right side of FIG. 8A is provided to penetrate the conductive layer 26. Alternatively, a structure in which, as illustrated in FIG. 8B, the opening 15 is not provided in a part overlapping with the conductive layer 26 can be employed.

FIG. 8C illustrates an example in which neither the conductive layer 23 nor the insulating layer 22 is provided. In this example, the conductive layer 26 serves as the gate electrode, and the insulating layer 27 serves as the gate insulating layer. The insulating layer 44 serving as a protective layer is provided in contact with the top and side surfaces of the semiconductor layer 21 in the opening 20. The insulating layer 44 is provided in contact with the insulating layers 27 and 12 in the opening 15.

In the example illustrated in FIG. 8C, the conductive layer 26 serving as the gate electrode surrounds the semiconductor layer 21; thus, this structure can also be referred to as a gate-all-around (GAA) structure. Meanwhile, in the structure illustrated in FIGS. 1A to 1C and the like, the semiconductor layer 21 surrounds the conductive layer 23 serving as the gate electrode; this can also be referred to as a transistor having a channel-all-around (CAA) structure.

### Manufacturing Method Example

Next, a method for manufacturing the semiconductor device of one embodiment of the present invention is described. Here, the structure illustrated in FIG. 1 as an example is described.

Note that the thin films included in the semiconductor device (e.g., the insulating films, the semiconductor films, and the conductive films) can be formed by a sputtering method, a chemical vapor deposition (CVD) method, a vacuum evaporation method, a pulsed laser deposition (PLD) method, an atomic layer deposition (ALD) method, or the like.

Alternatively, the thin films (e.g., the insulating films, the semiconductor films, and the conductive films) included in the semiconductor device can be formed by a method such as spin coating, dipping, spray coating, inkjet printing, dispensing, screen printing, or offset printing or with a doctor knife, a slit coater, a roll coater, a curtain coater, or a knife coater.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a film of a compound such as an oxide, a nitride, or a carbide is formed by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A thermal CVD method yields a film with few defects because of no plasma damage during deposition.

As the ALD method, a thermal ALD method, in which a precursor and a reactant react with each other only by a thermal energy, a PEALD method, in which a reactant excited by plasma is used, or the like can be used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a CVD method.

By a CVD method, a film with a certain composition can be formed by adjusting the flow rate ratio of the source gases. For example, a CVD method enables formation of a film whose composition is gradually changed by changing the flow rate ratio of the source gases during deposition. In the case where a film is formed while the flow rate ratio of the source gases is changed, as compared with the case where a film is formed using a plurality of deposition chambers, the time taken for the deposition can be shortened because the time taken for transfer and pressure adjustment is omitted. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the cycle number of precursor deposition is controlled, whereby a film with a desired composition can be formed. Furthermore, a film whose composition is continuously changed can be formed as in the CVD method.

To process thin films included in the semiconductor device, a photolithography method or the like can be employed. Besides, a nanoimprinting method, a sandblasting method, a lift-off method, or the like can be employed to process thin films. Alternatively, island-shaped thin films can be directly formed by a deposition method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure can also be performed by liquid immersion exposure technique. As the light for exposure, extreme ultraviolet (EUV) light or X-rays can also be used. Instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used. A wet etching method is mainly suitable for isotropic etching. Meanwhile, a dry etching method can be employed for both isotropic etching and anisotropic etching depending on the etching apparatus and the etching condition.

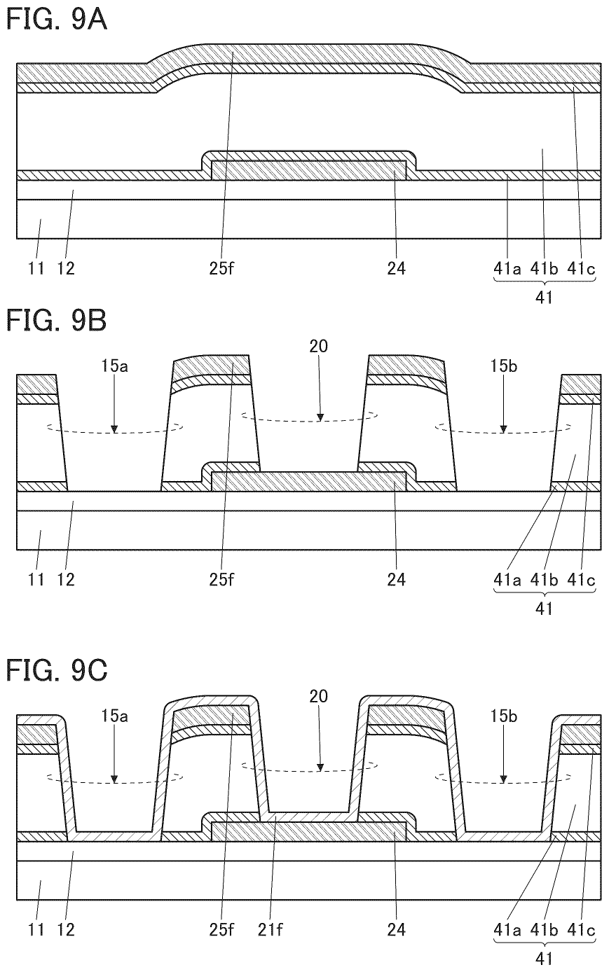

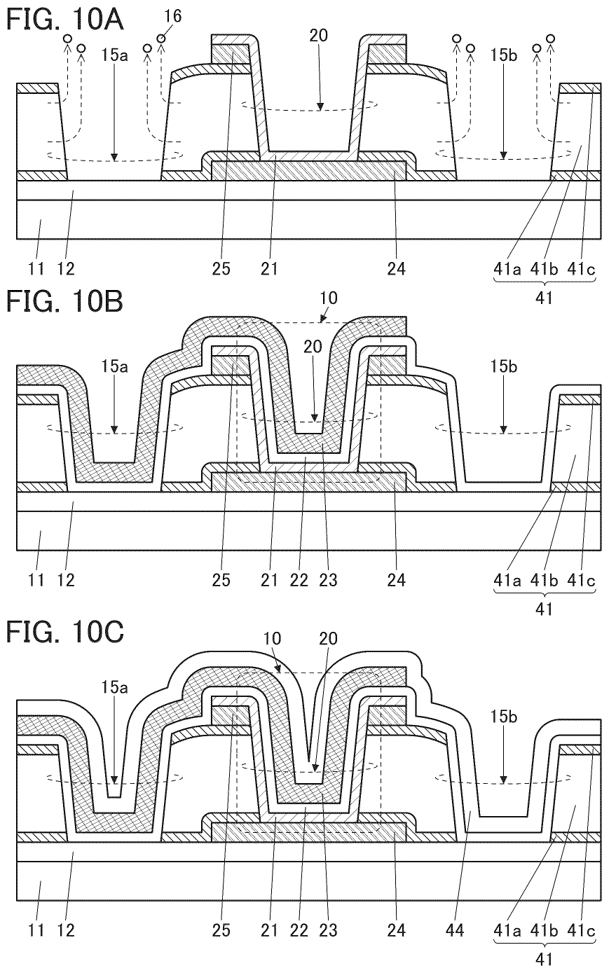

FIG. 9A to FIG. 10C are cross-sectional views of steps in a method for manufacturing a semiconductor device described below.

First, the substrate 11 is prepared, and the insulating layer 12 is formed over the substrate 11.

As the substrate 11, a substrate that has heat resistance high enough to withstand at least heat treatment performed later can be used. When an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate of silicon, silicon carbide, or the like; a compound semiconductor substrate of silicon germanium, gallium nitride, or the like; or an SOI substrate.

An inorganic insulating film such as a silicon oxide film or a silicon oxynitride film can be used as the insulating layer 12. The insulating layer 12 can be formed by a sputtering method, a CVD method, an MBE method, a PLD method, an ALD method, or the like. In the case where the formation surface of the insulating layer 12 is not flat, planarization treatment is preferably performed after the formation of the insulating layer 12 so that the insulating layer 12 has a flat top surface.

Next, a conductive film is formed over the insulating layer 12, a resist mask is formed over the conductive film, and an unnecessary portion of the conductive film is removed by etching, whereby the conductive layer 24 is formed. The conductive film to be the conductive layer 24 can be formed by a formation method such as a sputtering method, a CVD method, or an ALD method.

Then, the insulating layers 41a, 41b, and 41c are formed over the conductive layer 24 and the insulating layer 12. The insulating layers 41a, 41b, and 41c can independently be formed by a sputtering method, a CVD method, an MBE method, a PLD method, an ALD method, or the like as appropriate. Insulating films used for the insulating layers 41a and 41c preferably have compositions or constituent elements different from that of an insulating film used for the insulating layer 41b.

Furthermore, the thicknesses of the insulating layers 41a, 41b, and 41c affect the channel length of the transistor; thus, it is important to prevent a variation in the thickness of each of the insulating layers 41a, 41b, and 41c.

The insulating layer 41b is to be a film in contact with the semiconductor layer 21 later and thus is preferably an oxide film including a large amount of oxygen so that oxygen is released by heating and including a small amount of hydrogen. The insulating layer 41b can be formed by a deposition method such as a PECVD method, a sputtering method, or an ALD method, and is particularly preferably formed by a sputtering method. In particular, when a gas containing not hydrogen but oxygen is used as a deposition gas, the insulating layer 41b including an extremely small amount of hydrogen and an excess amount of oxygen can be formed. When the insulating layer 41b is formed in this manner, oxygen can be supplied to the channel formation region of the semiconductor layer 21 from the insulating layer 41b, so that oxygen vacancies can be reduced.

In addition, treatment of supplying oxygen to the insulating layer 41b can be performed after the formation of the insulating layer 41b but before the formation of the insulating layer 41c. Examples of a method for supplying oxygen to the insulating layer 41b include heat treatment in an oxygen atmosphere and plasma treatment in an oxygen atmosphere. Alternatively, an oxide film can be formed over the top surface of the insulating layer 41b by a sputtering method in an oxygen atmosphere to supply oxygen. After that, the oxide film can also be removed. Alternatively, oxygen (including any of an oxygen radical, an oxygen atom, and an oxygen ion) can be supplied by an ion implantation method, an ion doping method, a plasma immersion ion implantation method, or the like.

Then, a conductive film 25f is formed over the insulating layer 41c (FIG. 9A). The conductive film 25f can be formed by a deposition method such as a sputtering method, a CVD method, an MBE method, a PLD method, or an ALD method.

After that, the opening 20 reaching the conductive layer 24 and the openings 15a and 15b reaching the insulating layer 12 are formed in the conductive film 25f and the insulating layers 41c, 41b, and 41a (FIG. 9B).

When the openings 20, 15a, and 15b are formed in the insulating layers 41c, 41b, and 41a, the conductive film 25f can be used as a hard mask. At this time, first, an opening is formed in the conductive film 25f using a resist mask. After that, the insulating layers 41c, 41b, and 41a are etched in this order with the conductive film 25f as a mask, so that the openings 20, 15a, and 15b can be formed. Note that the resist mask can be removed after the etching of the conductive film 25f, during the etching of the insulating layers 41c, 41b, and 41a, or after the formation of the openings 20, 15a, and 15b.

The conductive film 25f and the insulating layers 41c, 41b, and 41a are etched by dry etching, whereby the minute openings 20, 15a, and 15b can be formed. Without limitation to this, the layers can be processed by a wet etching method and/or a dry etching method.

The sidewall of the opening 20 preferably has a shape nearly perpendicular to the top surface of the conductive layer 24, in which case the area of the opening 20 can be reduced. This structure can reduce the area occupied by the transistor. The sidewall of the opening 20 can have a tapered shape. The tapered shape improves the coverage with a film formed in the opening 20. Note that the same applies to the openings 15a and 15b.

The maximum width of the opening 20 (the maximum diameter in the case where the opening 20 is circular in the plan view) is preferably as small as possible. For example, the maximum width of the opening 20 is preferably less than or equal to 2 μm, less than or equal to 1 μm, less than or equal to 500 nm, less than or equal to 300 nm, less than or equal to 150 nm, less than or equal to 100 nm, less than or equal to 60 nm, less than or equal to 50 nm, less than or equal to 40 nm, less than or equal to 30 nm, or less than or equal to 20 nm and greater than or equal to 5 nm. In particular, in order to process the opening 20 extremely finely, an electron beam or short-wavelength light such as EUV light is preferably used for the lithography method.

Here, the openings 20, 15a, and 15b are formed in the same step at the same time. In that case, the manufacturing process can be simplified. Note that the layer on the bottom of the opening 20 is different from that of the openings 15a and 15b. Thus, depending on the etching conditions of the insulating layer 41 (specifically, the insulating layer 41c), the upper portion of one or both of the conductive layer 24 on the bottom of the opening 20 and the insulating layer 12 on the bottom of the openings 15a and 15b is partly etched in some cases.

Note that the formation step of the openings 15a and 15b can be different from that of the opening 20. That can make the formation of the various openings 15 illustrated as examples in FIG. 5 different from that of the opening 20.

Next, heat treatment can be performed. The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment can be performed under a reduced pressure. Alternatively, the heat treatment can be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen. By the above-described heat treatment, impurities such as water and hydrogen included in the insulating layer 41, for example, can be reduced before an oxide semiconductor film to be the semiconductor layer is formed.

The gas used in the above-described heat treatment is preferably highly purified. For example, the amount of moisture contained in the gas used in the above-described heat treatment is 1 ppb or less, preferably 0.1 ppb or less, and further preferably 0.05 ppb or less. The heat treatment using a highly purified gas can, for example, prevent the entry of moisture into the insulating layer 41 as much as possible.

Then, a semiconductor film 21f to be the semiconductor layer 21 is formed to cover the conductive film 25f, the insulating layer 41c, the openings 20, 15a, and 15b, and the like (FIG. 9C).

An oxide semiconductor film can be used as the semiconductor film 21f. The oxide semiconductor film can be formed as appropriate by a sputtering method, a CVD method, an MBE method, a PLD method, an ALD method, or the like. In the case where the sidewall of the opening 20 has a tapered shape, the oxide semiconductor film can be formed by a sputtering method. In the case where the sidewall of the opening 20 is substantially perpendicular to the top surface of the substrate 11 or has an inverse tapered shape, the oxide semiconductor film is preferably formed by a film formation method with favorable coverage, and is further preferably formed by a CVD method, an ALD method, or the like. For example, In—Ga—Zn oxide is formed as the oxide semiconductor film.

During or after the formation of the oxide semiconductor film, microwave treatment is preferably performed in an oxygen-containing atmosphere so that the impurity concentration in the oxide semiconductor film can be reduced. Examples of the impurity especially include hydrogen and carbon. The microwave treatment can increase the crystallinity of the oxide semiconductor film in some cases. Here, the microwave treatment refers to, for example, treatment using an apparatus including a power source for generating high-density plasma using microwaves.

In the case where the semiconductor layer 21 has a stacked-layer structure, the layers can be formed by the same method or different methods from each other. For example, in the case where the semiconductor layer 21 has a stacked-layer structure of two layers, the lower oxide semiconductor film can be formed by a sputtering method and the upper oxide semiconductor film can be formed by an ALD method. An oxide semiconductor film formed by a sputtering method is likely to have crystallinity. Thus, when an oxide semiconductor film having crystallinity is provided as the lower oxide semiconductor film, the crystallinity of the upper oxide semiconductor film can be increased. Even when a pin hole, disconnection, or the like is formed in the lower oxide semiconductor film formed by a sputtering method, the upper oxide semiconductor film formed by an ALD method with favorable coverage can fill the portion.

The semiconductor film is preferably formed by a sputtering method using a metal oxide target, for example.

The semiconductor film is preferably a dense film with as few defects as possible. The semiconductor film is preferably a highly purified film in which impurities such as hydrogen and water are reduced as much as possible. It is particularly preferable to use a metal oxide film having crystallinity as the semiconductor film.

In forming the metal oxide film, an oxygen gas and an inert gas (such as a helium gas, an argon gas, or a xenon gas) can be mixed. Note that the higher the proportion of the oxygen gas in the whole deposition gas (hereinafter also referred to as oxygen flow rate ratio) is in forming the metal oxide film, the higher the crystallinity of the metal oxide film can be, achieving a highly reliable transistor. By contrast, the lower the oxygen flow rate ratio is, the lower the crystallinity of the metal oxide film is, offering a transistor with increased on-state current.

In forming the metal oxide film, as the substrate temperature becomes higher, a denser metal oxide film having higher crystallinity can be formed. On the other hand, as the substrate temperature becomes lower, a metal oxide film having lower crystallinity and higher electrical conductivity can be formed.

The metal oxide film can be formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably set to be higher than or equal to room temperature and lower than 140° C. because the productivity is increased. When the metal oxide film is formed at a substrate temperature set to room temperature or without intentional heating, the metal oxide film can have low crystallinity.

In the case of employing an ALD method, a deposition method such as a thermal ALD method or a plasma enhanced ALD (PEALD) method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the semiconductor layer 21 including a metal oxide can be formed by an ALD method using a precursor containing a constituent metal element and an oxidizer.

For example, In—Ga—Zn oxide can be formed using a precursor containing indium, a precursor containing gallium, and a precursor containing zinc. Alternatively, a precursor containing indium and a precursor containing gallium and zinc can be used.

As the precursor containing indium, triethylindium, tris(2,2,6,6-tetramethyl-3,5-heptanedionato)indium, cyclopentadienylindium, indium(III) chloride, (3-(dimethylamino)propyl)dimethylindium, or the like can be used.

As the precursor containing gallium, trimethylgallium, triethylgallium, tris(dimethylamide)gallium(III), gallium(III) acetylacetonate, tris(2,2,6,6-tetramethyl-3,5-heptanedionato)gallium, dimethylchlorogallium, diethylchlorogallium, gallium(III) chloride, or the like can be used.

As the precursor containing zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer.

As a method for controlling the composition of a film to be formed, adjusting the flow rate ratio, flowing time, flowing order, or the like of the source gases is given. By adjusting such conditions, a film in which composition changes continuously can be formed. Furthermore, two or more films having different compositions can be formed successively.

Then, oxygen can be supplied from the insulating layer 41b to the semiconductor film 21f by heat treatment. By the heat treatment, hydrogen in the semiconductor film 21f, water adsorbed on the surface of the semiconductor film 21f, and the like can be removed. For the method of the heat treatment, the above description can be referred to.

Then, an unnecessary part of the semiconductor film 21f is removed by etching to form the semiconductor layer 21. Then, an unnecessary part of the conductive film 25f is removed by etching to form the conductive layer 25 (see FIG. 10A). Here, an example in which the semiconductor layer 21 and the conductive layer 25 are processed with the use of the same photomask is described. This is preferred because the manufacturing process can be simplified. Note that the semiconductor layer 21 and the conductive layer 25 can also be processed with the use of different photomasks.

After the formation of the semiconductor layer 21, the sidewalls of the openings 15a and 15b are each exposed. Specifically, at least part of the insulating layer 41b is exposed. In this state, heat treatment can be performed to release excess oxygen 16 in the insulating layer 41b from the openings 15a and 15b to the outside. Note that the heat treatment here can be omitted in the case where treatment (e.g., a film formation step) at high temperature is performed later because oxygen can be released from the insulating layer 41b in this treatment. Examples of the treatment at high temperature include a step of forming the insulating layer 22 and a step of forming the insulating layer 44.

The heat treatment can be performed in an atmosphere including a noble gas or nitrogen. Alternatively, the heating can be performed in a clean dry air (CDA) atmosphere. When an atmosphere containing oxygen is employed and the partial pressure of oxygen in the atmosphere is controlled, the amount of released oxygen from the insulating layer 41b can be controlled. It is preferable that the above atmosphere used for the heat treatment contain hydrogen, water, or the like as little as possible. An electric furnace, a rapid thermal anneal (RTA) apparatus, or the like can be used for the heat treatment. The use of an RTA apparatus can shorten the heat treatment time. The use of an electric furnace facilitates control of the partial pressure of a gas to be used.

The temperature and time of the heat treatment can be set in accordance with the film quality of the insulating layer 41b, the distance between the opening 20 and the opening 15a or 15b, the amount of oxygen to be released, and the like. The total amount of oxygen released from the insulating layer 41b increases in proportion to the treatment temperature and the treatment time.

For example, in the case where an electric furnace and a CDA atmosphere are employed, the treatment time (excluding the temperature rising time and the temperature decreasing time) is preferably longer than or equal to 30 minutes and shorter than or equal to 8 hours, further preferably longer than or equal to 45 minutes and shorter than or equal to 4 hours, still further preferably longer than or equal to 50 minutes and shorter than or equal to 2 hours, typically shorter than or equal to 1 hours. The treatment temperature is higher than or equal to 100 (C and lower than or equal to 550 (C, preferably higher than or equal to 200 (C and lower than or equal to 500 (C, and further preferably higher than or equal to 250 (C and lower than or equal to 450 (C.

Then, the insulating layer 22 is formed to cover the semiconductor layer 21, the conductive layer 25, the insulating layer 41, the insulating layer 12, and the like. The insulating layer 22 can be formed by a sputtering method, a CVD method, an MBE method, a PLD method, an ALD method, or the like as appropriate.

The insulating layer 22 is preferably provided to have a thickness as uniform as possible on the side surface of the semiconductor layer 21 in the opening 20. Thus, the insulating layer 22 is particularly preferably formed by a CVD method or an ALD method, which is a deposition method with extremely excellent coverage. In the case where the opening 20 has a sidewall with a tapered shape, the insulating layer 22 can be formed by a film formation method such as a sputtering method.

After the formation of the insulating layer 22, heat treatment for release of oxygen from the insulating layer 41b can also be performed. This enables excess oxygen to be released from the insulating layer 41b to the outside through the insulating layer 22.

Next, a conductive film is formed to cover the insulating layer 22 and an unnecessary portion is removed by etching, whereby the conductive layer 23 is formed (FIG. 10B).

Through the above process, the transistor 10 can be fabricated.

Then, the insulating layer 44 is formed to cover the conductive layer 23 and the insulating layer 22 (FIG. 10C). The insulating layer 44 can be formed in a manner similar to that of the insulating layer 41a or 41b.

After the formation of the insulating layer 44, heat treatment for release of oxygen from the insulating layer 41b can be performed. This enables excess oxygen to be released from the insulating layer 41b to the outside through the insulating layers 22 and 44.

The heat treatment for release of oxygen from the insulating layer 41b can be performed at any timing after the formation of the semiconductor layer 21. The heat treatment can be performed one or more times. The treatment (e.g., a film formation step) at high temperature performed after the formation of the semiconductor layer 21 can also serve as the heat treatment in some cases.

The above is the description of the manufacturing method example.

At least part of any of the structure examples, the drawings corresponding thereto, and the like described in this embodiment can be implemented in combination with any of the other structure examples, the other drawings corresponding thereto, and the like as appropriate.

### Embodiment 2

In this embodiment, a display device using the semiconductor device of one embodiment of the present invention will be described with reference to the drawings.

The display device in this embodiment can be a high-resolution display device or large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module which is mounted with an integrated circuit (IC) by a chip on glass (COG) method, a chip on film (COF) method, or the like, and the like.

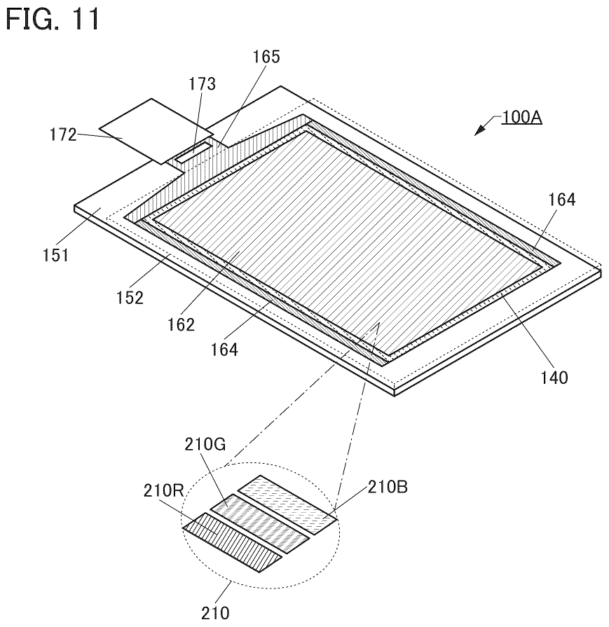

FIG. 11 is a perspective view of a display device 100A.

In the display device 100A, a substrate 152 and a substrate 151 are bonded to each other.

In FIG. 11, the substrate 152 is indicated by a dashed line.

The display device 100A includes a display portion 162, a connection portion 140, a circuit portion 164, a wiring 165, and the like. FIG. 11 illustrates an example where an IC 173 and an FPC 172 are implemented onto the display device 100A. Thus, the structure illustrated in FIG. 11 can be regarded as a display module including the display device 100A, the IC, and the FPC.

The connection portion 140 is provided outside the display portion 162. The connection portion 140 can be provided along one or more sides of the display portion 162. The number of connection portions 140 can be one or more. FIG. 11 illustrates an example where the connection portion 140 is provided to surround the four sides of the display portion 162. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 can include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or from the IC 173.

FIG. 11 illustrates an example where the IC 173 is provided on the substrate 151 by a COG method, a COF method, or the like. An IC including one or both of a scan line driver circuit and a signal line driver circuit can be used as the IC 173, for example. Note that the display device 100A and the display module are not necessarily provided with an IC. The IC can be mounted on the FPC by a COF method or the like.

The semiconductor device of one embodiment of the present invention can be used for one or both of the display portion 162 and the circuit portion 164 of the display device 100A, for example. The semiconductor device of one embodiment of the present invention can also be used for the IC 173.

When the semiconductor device of one embodiment of the present invention is used for a pixel circuit of the display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the semiconductor device of one embodiment of the present invention has favorable electrical characteristics, a display device can have increased reliability by using the semiconductor device.

The display portion 162 is a region where an image is displayed and a plurality of pixels 210 are periodically arranged in the display device 100A. FIG. 11 shows an enlarged view of one pixel 210.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement.

The pixel 210 illustrated in FIG. 11 includes a subpixel 210R that emits red light, a subpixel 210G that emits green light, and a subpixel 210B that emits blue light.

Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials can be used.

As the liquid crystal element, a transmissive liquid crystal element, a reflective liquid crystal element, a transflective liquid crystal element, or the like can be used.

As the light-emitting element, a self-luminous light-emitting element such as an LED, an organic LED (OLED), or a semiconductor laser can be used. Examples of the LED include a mini LED and a micro LED.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting element can emit infrared, red, green, blue, cyan, magenta, yellow, or white light, for example. When the light-emitting element has a microcavity structure, the color purity can be increased.

One of a pair of electrodes of the light-emitting element serves as an anode, and the other electrode serves as a cathode. The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

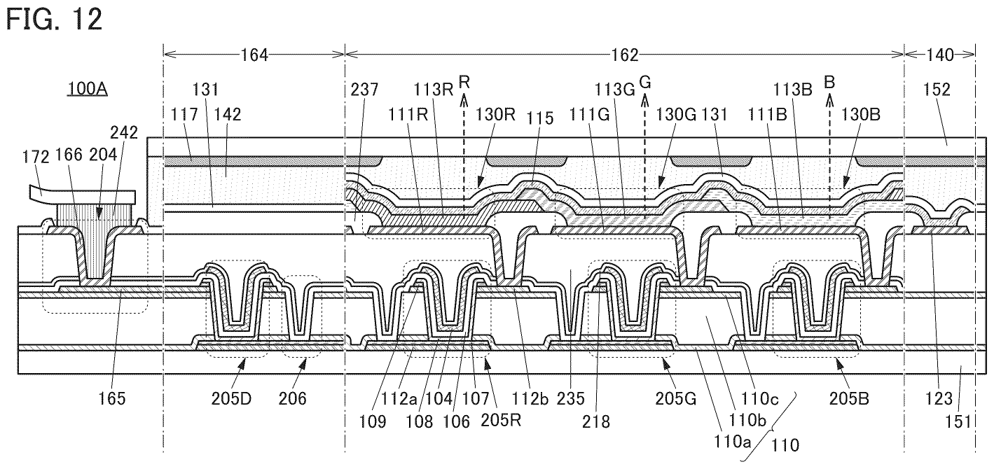

FIG. 12 illustrates an example of cross sections of part of a region including the FPC 172, part of the circuit portion 164, part of the display portion 162, part of the connection portion 140, and part of a region including an end portion of the display device 100A.

The display device 100A illustrated in FIG. 12 includes transistors 205D, 205R, 205G, and 205B, light-emitting elements 130R, 130G, and 130B, and the like between the substrates 151 and 152. The light-emitting elements 130R, 130G, and 130B are display elements included in the subpixel 210R that emits red light, the subpixel 210G that emits green light, and the subpixel 210B that emits blue light, respectively.

The display device 100A employs a side-by-side (SBS) structure. The SBS structure can optimize materials and structures of light-emitting elements and thus can extend freedom of choice of materials and structures, whereby the luminance and the reliability can be easily improved.

The display device 100A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistors 205D, 205R, 205G, and 205B are formed over the substrate 151. These transistors can be fabricated through the same process.

An insulating layer 110 is provided over the substrate 151, and the transistors 205D, 205R, 205G, and 205B are provided in opening portions provided in the insulating layer 110. The insulating layer 110 has a structure in which the insulating layers 110a, 110b, and 110c are stacked in this order from the substrate 151 side.

In this embodiment, an example where the transistor of one embodiment of the present invention, which includes an oxide semiconductor as a semiconductor and in which parasitic capacitance is reduced, is used as each of the transistors 205D, 205R, 205G, and 205B is described. The transistors 205R, 205G, and 205B serve as, for example, driving transistors controlling current flowing through the light-emitting elements. The transistor 205D provided in the circuit portion constitutes part of the circuit portion 164.

Specifically, each of the transistors 205D, 205R, 205G, and 205B includes a conductive layer 104 serving as a gate, an insulating layer 106 serving as a gate insulating layer, a conductive layer 109 serving as one of a source electrode and a drain electrode, a conductive layer 107 serving as the other of the source electrode and the drain electrode, a semiconductor layer 108, and the like. The conductive layers 109 and 107 are in contact with the semiconductor layer 108. In addition, a conductive layer 112a in contact with the conductive layer 107 and a conductive layer 112b in contact with the conductive layer 109 are provided. Each of the conductive layers 112a and 112b includes a conductive material having lower resistance than the conductive layers 107 and 109 and serves as a wiring. Here, a plurality of layers obtained by processing the same film are shown with the same hatching pattern.

As described above, the display device 100A includes the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. When one or both of the display portion 162 and the circuit portion 164 include the transistors of one embodiment of the present invention, the load of wirings can be reduced; thus, a display device capable of high-speed operation, a large-sized display device, or a display device with high resolution (with a large number of pixels) can be achieved. The description in the above embodiment can be referred to for the transistor of one embodiment of the present invention.

An opening portion 206 is provided in the vicinity of each of the transistors 205D, 205R, 205G, and 205B. An opening that penetrates the insulating layer 110 and reaches the conductive layer 107 is provided in the opening portion 206. Furthermore, the insulating layer 106 and an insulating layer 218 are provided to cover the opening portion 206. In the opening portion 206, the side surface of the insulating layer 110b is in contact with the insulating layer 106. This leads to higher reliability of the transistors 205D, 205R, 205G, and 205B.

Note that the transistor included in the display device of this embodiment is not limited to the transistor of one embodiment of the present invention. For example, the display device of this embodiment can include the transistor of one embodiment of the present invention and a transistor having another structure in combination.

The display device of this embodiment can include one or more of a planar transistor, a staggered transistor, and an inverted staggered transistor. A transistor included in the display device of this embodiment can have a top-gate structure or a bottom-gate structure. Gates can be provided above and below a semiconductor layer where a channel is formed.

A transistor including silicon in its channel formation region (a Si transistor) can be included in the display device of this embodiment. Examples of silicon include single crystal silicon, polycrystalline silicon, and amorphous silicon. In particular, a transistor including LTPS in a semiconductor layer (hereinafter also referred to as an LTPS transistor) can be used. The LTPS transistor has high field-effect mobility and excellent frequency characteristics. An amorphous silicon film can be uniformly formed over a large-area glass substrate; thus, a transistor including amorphous silicon in its semiconductor layer is excellent in productivity.

The display device of this embodiment can include a transistor including an oxide semiconductor (OS) typified by In—Ga—Zn oxide (also referred to as IGZO) in its channel formation region (such a transistor is referred to as an OS transistor). For example, the display device can include both a transistor including silicon in its semiconductor where a channel is formed and a transistor including an oxide semiconductor.

The transistor included in the circuit portion 164 and the transistor included in the display portion 162 can have the same structure or different structures. One structure or two or more kinds of structures can also be employed for a plurality of transistors included in the circuit portion 164. Similarly, one structure or two or more kinds of structures can be employed for a plurality of transistors included in the display portion 162.

All of the transistors included in the display portion 162 can be OS transistors or Si transistors. Alternatively, some of the transistors included in the display portion 162 can be OS transistors and the others can be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which the OS transistor is used as a transistor functioning as a switch for controlling electrical continuity and discontinuity between wirings and the LTPS transistor is used as a transistor for controlling current.

For example, one transistor included in the display portion 162 functions as a transistor for controlling current flowing through the light-emitting element and can also be referred to as a driving transistor. One of a source and a drain of the driving transistor is electrically connected to the pixel electrode of the light-emitting element.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material through which impurities such as water and hydrogen are less likely to be diffused is preferably used for the insulating layer 218. This is because the insulating layer 218 can function as a barrier layer. Such a structure can effectively inhibit diffusion of impurities into the transistors from the outside and increase the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 can have a stacked-layer structure of an organic insulating film and an inorganic insulating film. The outermost layer of the insulating layer 235 preferably functions as an etching protective layer. Thus, the formation of a depression in the insulating layer 235 can be inhibited in processing pixel electrodes 111R, 111G, and 111B, for example. Alternatively, a depression can be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 12 emits red light (R). The EL layer 113R includes a light-emitting layer that emits red light.

In a similar manner, the light-emitting element 130G includes the pixel electrode 111G, an EL layer 113G, and the common electrode 115. The light-emitting element 130G emits green light (G) and the EL layer 113G includes a light-emitting layer that emits green light.

In a similar manner, the light-emitting element 130B includes the pixel electrode 111B, an EL layer 113B, and the common electrode 115. The light-emitting element 130B emits blue light (B) and the EL layer 113B includes a light-emitting layer that emits blue light.

Although the EL layers 113R, 113G, and 113B have the same thickness in FIG. 12, the present invention is not limited thereto. The EL layers 113R, 113G, and 113B can have different thicknesses. For example, the thickness is preferably set in accordance with an optical path length for intensifying light emitted from the EL layers 113R, 113G, and 113B. Thus, a microcavity structure is achieved, and the color purity of light emitted from each light-emitting element can be improved.

The pixel electrode 111R is electrically connected to the conductive layer 112b included in the transistor 205R through an opening provided in the insulating layers 106, 218, and 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition (also referred to as a bank or a spacer). The insulating layer 237 can have a single-layer structure or a stacked-layer structure including one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light can be used also for the electrode through which light is not extracted. In that case, this electrode is preferably provided between the reflective layer and the EL layer. In other words, light emitted by the EL layer can be reflected by the reflective layer to be extracted from the display device.

As the material of the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium (Mg—Ag) and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided into an island shape. In FIG. 12, end portions of the EL layers 113R and 113G adjacent to each other overlap with each other, end portions of the EL layers 113G and 113B adjacent to each other overlap with each other, and end portions of the EL layers 113R and 113B adjacent to each other overlap with each other. When island-shaped EL layers are formed using a fine metal mask, end portions of the EL layers adjacent to each other may overlap with each other as illustrated in FIG. 12; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer can include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property, also referred to as a bipolar material) or a TADF material can be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer can further include one or both of a bipolar material and a TADF material.

Either a low molecular compound or a high molecular compound can be used in the light-emitting element, and an inorganic compound can also be included. Each layer included in the light-emitting element can be formed by any of the following methods: an evaporation method (including a vacuum evaporation method), a transfer method, a printing method, an inkjet method, a coating method, and the like.

The light-emitting element can employ a single structure (a structure including only one light-emitting unit) or a tandem structure (a structure including a plurality of light-emitting units). The light-emitting unit includes at least one light-emitting layer. The tandem structure is a structure in which a plurality of light-emitting units are connected in series with a charge-generation layer therebetween. The charge-generation layer has a function of injecting electrons into one of the two light-emitting units and injecting holes to the other when voltage is applied between the pair of electrodes. A tandem structure enables a light-emitting element capable of emitting light with high luminance. Furthermore, the tandem structure allows the amount of current needed for obtaining the same luminance to be reduced as compared to the case of using a single structure, and thus can improve the reliability. The tandem structure can be referred to as a stack structure.

In the case of using a tandem light-emitting element in FIG. 12, for example, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 12, a solid sealing structure is employed, in which a space between the substrate 152 and the substrate 151 is filled with the adhesive layer 142. Alternatively, a hollow sealing structure can be employed, in which the space is filled with an inert gas (e.g., nitrogen or argon). In that case, the adhesive layer 142 can be provided not to overlap with the light-emitting element. Alternatively, the space can be filled with a resin other than the frame-like adhesive layer 142.

The protective layer 131 is provided at least in the display portion 162, and preferably provided to cover the entire display portion 162. By providing the protective layer 131 over the light-emitting elements 130R, 130G, and 130B, the reliability of the light-emitting elements can be increased. The protective layer 131 is preferably provided to cover not only the display portion 162 but also the connection portion 140 and the circuit portion 164. It is further preferable that the protective layer 131 be provided to extend to the end portion of the display device 100A. Meanwhile, a connection portion 204 has a portion not provided with the protective layer 131 so that the FPC 172 and the conductive layer 166 are electrically connected to each other.

The protective layer 131 can be a single-layer structure or a stacked-layer structure including two or more layers. There is no limitation on the conductivity of the protective layer 131. For the protective layer 131, at least one of an insulating film, a semiconductor film, and a conductive film can be used. The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved. For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film can further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer.

Furthermore, the protective layer 131 can include an organic film. For example, the protective layer 131 can include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the wiring 165 is electrically connected to the FPC 172 through the conductive layer 166 and a connection layer 242. In this example, the wiring 165 is a single conductive layer obtained by processing the same conductive film as the conductive layer 112b. In this example, the conductive layer 166 is a single conductive layer obtained by processing the same conductive film as the pixel electrodes 111R, 111G, and 111B. On the top surface of the connection portion 204, the conductive layer 166 is exposed. Thus, the connection portion 204 and the FPC 172 can be electrically connected to each other through the connection layer 242.

The display device 100A has a top-emission structure. Light from the light-emitting element is emitted toward the substrate 152. For the substrate 152, a material having a high visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided over a region between adjacent light-emitting elements, in the connection portion 140, in the circuit portion 164, and the like.

A coloring layer such as a color filter can be provided on the surface of the substrate 152 on the substrate 151 side or over the protective layer 131. By providing the color filter so as to overlap with the light-emitting element, the color purity of light emitted from a pixel can be increased.

Moreover, a variety of optical members can be provided on the outside of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like can be provided as a surface protective layer on the outer surface of the substrate 152. For example, it is preferable to provide, as the surface protective layer, a glass layer or a silica layer (SiOx layer) because the surface contamination or damage can be prevented. The surface protective layer can be formed using diamond-like carbon (DLC), aluminum oxide (AlOx), a polyester-based material, a polycarbonate-based material, or the like. For the surface protective layer, a material having a high visible light transmittance is preferably used. The surface protective layer is preferably formed using a material with high hardness.

For each of the substrates 151 and 152, glass, quartz, ceramic, sapphire, a resin, a metal, an alloy, a semiconductor, or the like can be used. The substrate on the side from which light from the light-emitting element is extracted is formed using a material that transmits the light. When a flexible material is used for the substrates 151 and 152, the display device can have increased flexibility and a flexible display can be obtained. Furthermore, a polarizing plate can be used as at least one of the substrates 151 and 152.

For each of the substrates 151 and 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility can be used as at least one of the substrates 151 and 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

For the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. A two-component-mixture-type resin can be used. An adhesive sheet or the like can be used.

As the connection layer 242, an anisotropic conductive film (ACF), an anisotropic conductive paste (ACP), or the like can be used.

### [Display Device 100B]

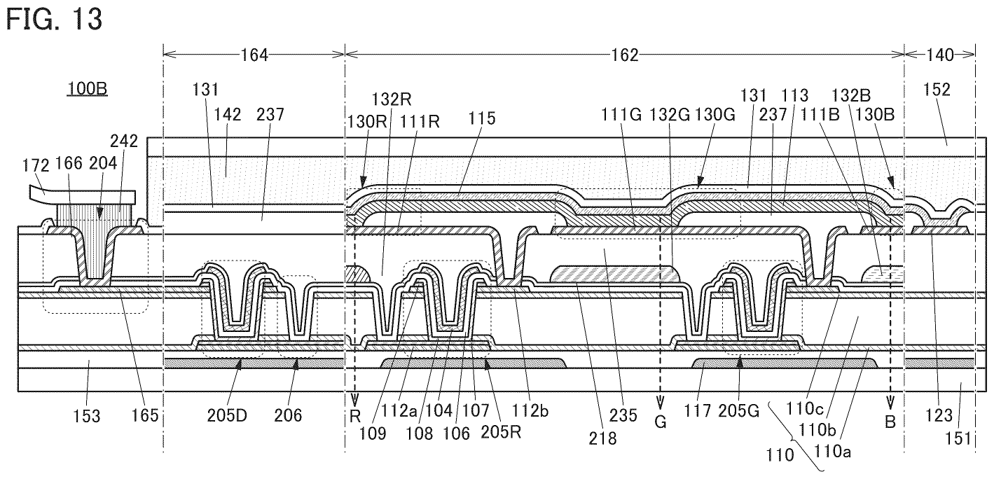

A display device 100B illustrated in FIG. 13 is different from the display device 100A mainly in being a bottom-emission display device and in that the subpixels of different colors include respective coloring layers (color filters or the like) and an EL layer 113 shared between the light-emitting elements, for example. Note that in the following description of display devices, the description of portions similar to those of the above-described display devices may be omitted.

Light from the light-emitting element is emitted toward the substrate 151. For the substrate 151, a material having a high visible-light-transmitting property is preferably used. By contrast, there is no limitation on the light-transmitting property of a material used for the substrate 152.

In the display device 100B illustrated in FIG. 13, the transistors 205D, 205R, 205G, and 205B (not shown), the light-emitting elements 130R, 130G, and 130B, the coloring layer 132R transmitting red light, the coloring layer 132G transmitting green light, the coloring layer 132B transmitting blue light, and the like are provided between the substrates 151 and 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 100B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 100B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 100B through the coloring layer 132B.

The EL layer 113 and the common electrode 115 are shared between the light-emitting elements 130R, 130G, and 130B. The number of manufacturing steps can be smaller in the case where the EL layer 113 is shared between the subpixels of different colors than the case where the subpixels of different colors include different EL layers.

The light-emitting elements 130R, 130G, and 130B illustrated in FIG. 13 emit white light, for example. When white light emitted from the light-emitting elements 130R, 130G, and 130B passes through the respective coloring layers 132R, 132G, and 132B, light of a desired color can be obtained.

The light-blocking layer 117 is preferably formed between the substrate 151 and the transistor. FIG. 13 illustrates an example where the light-blocking layers 117 are provided over the substrate 151, an insulating layer 153 is provided over the light-blocking layers 117, and the transistors 205D, 205R, 205G, and 205B (not illustrated) and the like are provided over the insulating layer 153. In addition, the coloring layers 132R, 132G, and 132B are provided over the insulating layer 218 and the insulating layer 235 is provided over the coloring layers 132R, 132G, and 132B.

A material having a good property of transmitting visible light is used for each of the pixel electrodes 111R, 111G, and 111B. A material that reflects visible light is preferably used for the common electrode 115. In the display device having a bottom-emission structure, a metal or the like having low resistance can be used for the common electrode 115; thus, a voltage drop due to the resistance of the common electrode 115 can be suppressed and the display quality can be improved.

The transistor of one embodiment of the present invention can be miniaturized and the area occupied by the transistor can be reduced, so that the aperture ratio of the pixel can be increased or the pixel size can be reduced in the display device having a bottom-emission structure.

In the case of employing a microcavity structure, the light-emitting elements 130R, 130G, and 130B each emit light with a specific wavelength, which is intensified, in white light emitted from the EL layer 113. Here, even with such a microcavity structure, a light-emitting element including an EL layer that emits white light is referred to as a white-light-emitting element.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element can be configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red and green light and a light-emitting unit that emits blue light; a three-unit tandem structure including a light-emitting unit that emits blue light, a light-emitting unit that emits yellow, yellow-green, or green light, and a light-emitting unit that emits blue light in this order; and a three-unit tandem structure including a light-emitting unit that emits blue light, a light-emitting unit that emits yellow, yellow-green, or green light and red light, and a light-emitting unit that emits blue light in this order. Examples of the stacked structure of light-emitting units include, from an anode side, a two-unit structure of B and Y; a two-unit structure of B and a light-emitting unit X; a three-unit structure of B, Y, and B; and a three-unit structure of B, X, and B. Examples of the stacked structure of light-emitting layers in the light-emitting unit X include, from an anode side, a two-layer structure of R and Y; a two-layer structure of R and G; a two-layer structure of G and R; a three-layer structure of G, R, and G; and a three-layer structure of R, G, and R. Another layer can be provided between two light-emitting layers.

Alternatively, the light-emitting elements 130R, 130G, and 130B illustrated in FIG. 13 can emit blue light, for example. In this case, the EL layer 113 includes one or more light-emitting layers that emit blue light. In the subpixel 210B that emits blue light, blue light emitted from the light-emitting element 130B can be extracted. In each of the subpixel 210R that emits red light and the subpixel 210G that emits green light, a color conversion layer is provided between the light-emitting element 130R or 130G and the substrate 151 so that blue light emitted from the light-emitting element 130R or 130G is converted into light with a longer wavelength, whereby red light or green light can be extracted. Furthermore, it is preferable that the coloring layer 132R be provided between the color conversion layer and the substrate 151 on an optical path of light emitted by the light-emitting element 130R, and the coloring layer 132G be provided between the color conversion layer and the substrate 151 on an optical path of light emitted by the light-emitting element 130G. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### [Display Device 100C]

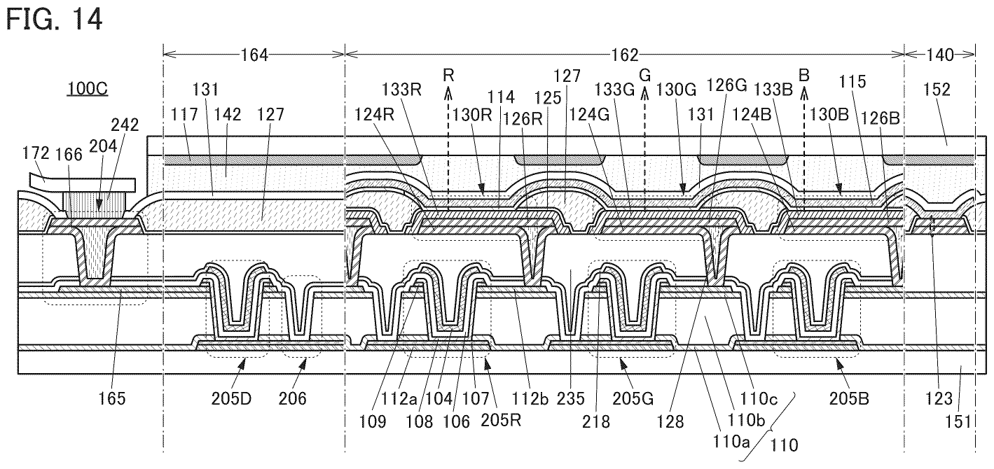

A display device 100C illustrated in FIG. 14 is an example of a display device having a metal maskless (MML) structure. In other words, the display device 100C includes a light-emitting element that is formed without using a fine metal mask. The stacked-layer structure from the substrate 151 to the insulating layer 235 and the stacked-layer structure from the protective layer 131 to the substrate 152 are similar to those in the display device 100A; therefore, detailed description thereof is omitted.

In FIG. 14, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 14 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

In a similar manner, the 1 light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 14 emits green light (G). The layer 133G includes a light-emitting layer that emits green light.

In a similar manner, the light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 14 emits blue light (B). The layer 133B includes a light-emitting layer that emits blue light.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, only the layers 133R, 133G, and 133B are sometimes referred to as island-shaped EL layers, EL layers formed in an island shape, or the like, in which case the common layer 114 is not included in the EL layer.

The layers 133R, 133G, and 133B are apart from each other. When the EL layer is provided in an island shape for each light-emitting element, leakage current between adjacent light-emitting elements can be inhibited. This can prevent crosstalk due to unintended light emission, so that a display device with extremely high contrast can be obtained.

Although the layers 133R, 133G, and 133B have the same thickness in FIG. 14, the present invention is not limited thereto. The layers 133R, 133G, and 133B can have different thicknesses.

The conductive layer 124R is electrically connected to the conductive layer 112b included in the transistor 205R through an opening provided in the insulating layers 106, 218, and 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in the depression of the conductive layers 124R, 124G, and 124B.

The layer 128 has a function of filling the depressions formed by the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 can be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 14 illustrates an example where a top surface of the layer 128 includes a flat portion, the shape of the layer 128 is not particularly limited. The top surface of the layer 128 can include at least one of a convex surface, a concave surface, and a flat surface.

The level of the top surface of the layer 128 and the level of the top surface of the conductive layer 124R can be the same or substantially the same, or can be different from each other. For example, the level of the top surface of the layer 128 can be either lower or higher than the level of the top surface of the conductive layer 124R.

An end portion of the conductive layer 126R can be aligned with an end portion of the conductive layer 124R or can cover a side surface of the end portion of the conductive layer 124R. The end portions of the conductive layers 124R and 126R each preferably have a tapered shape. Specifically, the end portions of the conductive layers 124R and 126R each preferably have a tapered shape with a taper angle less than 90(. In the case where the end portions of the pixel electrodes have a tapered shape, the layer 133R provided along side surfaces of the pixel electrodes has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top and side surfaces of the conductive layer 126R are covered with the layer 133R. Similarly, the top and side surfaces of the conductive layers 126G are covered with the layer 133G, and the top and side surfaces of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layers 133R, 133G, and 133B are covered with the insulating layers 125 and 127. The common layer 114 is provided over the layers 133R, 133G, and 133B and the insulating layers 125 and 127, and the common electrode 115 is provided over the common layer 114. The common layer 114 and the common electrode 115 are each one continuous film shared by a plurality of light-emitting elements.

In FIG. 14, the insulating layer 237 illustrated in FIG. 12 or the like is not provided between the conductive layer 126R and the layer 133R. That is, an insulating layer (also referred to as a partition wall, a bank, a spacer, or the like) covering and in contact with a top end portion of the pixel electrode is not provided in the display device 100C. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layers 133R, 133G, and 133B each include the light-emitting layer. The layers 133R, 133G, and 133B each preferably include the light-emitting layer and a carrier-transport layer (an electron-transport layer or a hole-transport layer) over the light-emitting layer. Alternatively, the layers 133R, 133G, and 133B each preferably include a light-emitting layer and a carrier-blocking layer (a hole-blocking layer or an electron-blocking layer) over the light-emitting layer. Alternatively, the layers 133R, 133G, and 133B each preferably include a light-emitting layer, a carrier-blocking layer over the light-emitting layer, and a carrier-transport layer over the carrier-blocking layer. Since the surfaces of the layers 133R, 133G, and 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 can be a stack of an electron-transport layer and an electron-injection layer, or can be a stack of a hole-transport layer and a hole-injection layer. The common layer 114 is shared by the light-emitting elements 130R, 130G, and 130B.

Side surfaces of the layers 133R, 133G, and 133B are each covered with the insulating layer 125. The insulating layer 127 covers the side surfaces of the layers 133R, 133G, and 133B with the insulating layer 125 therebetween.

The side surfaces (and part of the top surfaces) of the layers 133R, 133G, and 133B are covered with at least one of the insulating layers 125 and 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layers 133R, 133G, and 133B. The insulating layer 125 in contact with the layers 133R, 133G, and 133B can prevent film separation of the layers 133R, 133G, and 133B, whereby the reliability of the light-emitting element can be increased.

The insulating layer 127 is provided over the insulating layer 125 to fill a depression formed by the insulating layer 125. The insulating layer 127 preferably covers at least part of the side surface of the insulating layer 125.

The insulating layers 125 and 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layers 125 and 127 are provided, a step is generated due to a difference between a region where the pixel electrode and the island-shaped EL layer are provided and a region where neither the pixel electrode nor the island-shaped EL layer is provided (region between the light-emitting elements). In the display device of one embodiment of the present invention, the step can be eliminated with the insulating layers 125 and 127, and the coverage with the common layer 114 and the common electrode 115 can be improved. Thus, connection defects caused by step disconnection can be inhibited. In addition, an increase in electric resistance, which is caused by local thinning of the common electrode 115 due to the level difference, can be inhibited.

For example, the top surface of the insulating layer 127 preferably has a smooth shape with high flatness. The top surface of the insulating layer 127 can include at least one of a flat surface, a convex surface, and a concave surface. For example, the top surface of the insulating layer 127 preferably has a smooth convex shape with high flatness.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 can have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 can have a stacked-layer structure of a film formed by an ALD method and a film formed by a sputtering method. The insulating layer 125 can have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as a function of less easily transmitting the substance). Alternatively, a barrier property refers to a function of capturing or fixing (also referred to as gettering) a particular substance.

When the insulating layer 125 has a function of the barrier insulating layer or a gettering function, entry of impurities (typically, at least one of water and oxygen) that would be diffused into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, one or both of the hydrogen concentration and the carbon concentration in the insulating layer 125 are preferably sufficiently low.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer including an organic material can be favorably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 can be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist can be used as the photosensitive organic resin. As the photosensitive organic resin, either a positive-type material or a negative-type material can be used.

The insulating layer 127 can be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferred, in which case the effect of blocking visible light is enhanced. In particular, mixing color filter materials of three or more colors enables the formation of a black or nearly black resin layer.

### [Display Device 100D]

Light-emitting elements are used as display elements in the above-described example, whereas the following example below shows a liquid crystal display device where liquid crystal elements are used as display elements.

Any of elements with various structures can be used as the liquid crystal elements included in the display device. Typically, a transmissive liquid crystal element employing a vertical alignment (VA) mode, a fringe field switching (FFS) mode, an in-plane switching (IPS) mode, or the like can be used. Instead of a transmissive liquid crystal element, a reflective liquid crystal element or a transflective liquid crystal element can be used as the liquid crystal element. The display device is preferably a normally black liquid crystal display device.

Examples of the VA mode include a multi-domain vertical alignment (MVA) mode, a patterned vertical alignment (PVA) mode, and an advanced super view (ASV) mode.

The liquid crystal element can employ a variety of modes. The liquid crystal element can employ, for example, a twisted nematic (TN) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an electrically controlled birefringence (ECB) mode, or a guest-host mode, in addition to the VA mode, an FFS mode, and an IPS mode.

Here, the liquid crystal display device is a display device that controls transmission and non-transmission of light by utilizing polarized light and an optical modulation action of a liquid crystal. The optical modulation action of a liquid crystal is controlled by an electric field applied to the liquid crystal (including a horizontal electric field, a vertical electric field, or an oblique electric field). As the liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions. As the liquid crystal material, a positive liquid crystal or a negative liquid crystal can be used, and an appropriate liquid crystal material can be used depending on the mode and design to be used.

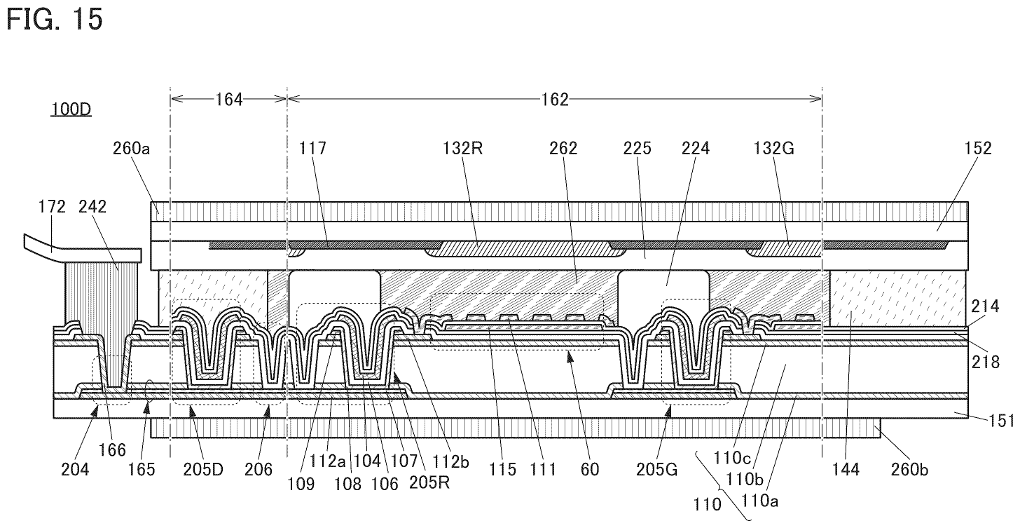

The display device 100D illustrated in FIG. 15 is an FFS liquid crystal display device.

The substrates 151 and 152 are bonded to each other with an adhesive layer 144. A region surrounded by the substrates 151 and 152 and the adhesive layer 144 is filled with liquid crystal 262. A polarizing plate 260a is positioned on the outer surface of the substrate 152, and a polarizing plate 260b is positioned on the outer surface of the substrate 151. Although not illustrated, a backlight can be provided outside the polarizing plate 260a or 260b.

The substrate 151 is provided with the transistors 205D, 205R, 205G, and 205B (not shown), the connection portion 204, a spacer 224, and the like. The conductive layers 112b included in the transistors 205R and 205G are electrically connected to a pixel electrode 111 of a liquid crystal element 60.

The substrate 152 is provided with the coloring layers 132R and 132G, the light-blocking layer 117, an insulating layer 225, and the like.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the common electrode 115, the pixel electrode 111, and the liquid crystal 262. The common electrode 115 is provided over the insulating layer 218, and an insulating layer 214 is provided over the common electrode 115. The pixel electrode 111 is provided over the insulating layer 214.

The pixel electrode 111 and the common electrode 115 transmit visible light. That is, the liquid crystal element 60 can be a transmissive liquid crystal element. For example, in the case where a backlight is provided on the substrate 151 side, light from the backlight which is polarized by the polarizing plate 260b passes through the substrate 151, the liquid crystal element 60, and the substrate 152, and then reaches the polarizing plate 260a. In that case, alignment of the liquid crystal 262 is controlled with a voltage that is applied between the pixel electrode 111 and the common electrode 115, and thus optical modulation of light can be controlled. In other words, the intensity of light emitted through the polarizing plate 260a can be controlled. Light other than one in a particular wavelength region of the incident light is absorbed by the coloring layer, and thus, emitted light is red light, for example.

As the polarizing plate 260a, a linear polarizing plate or a circularly polarizing plate can be used. An example of a circularly polarizing plate is a stack including a linear polarizing plate and a quarter-wave retardation plate. Reflection of external light can be reduced with a circularly polarizing plate used as the polarizing plate 260a.

In the case where a circularly polarizing plate is used as the polarizing plate 260a, a circularly polarizing plate or a general linear polarizing plate can be used as the polarizing plate 260b. The cell gap, alignment, driving voltage, and the like of the liquid crystal element used as the liquid crystal element 60 can be controlled in accordance with the kinds of polarizing plates used as the polarizing plates 260a and 260b so that desirable contrast can be obtained.

The connection portion 204 is provided in a region near an end portion of the substrate 151. In the connection portion 204, the wiring 165 is electrically connected to the FPC 172 through the conductive layer 166 and the connection layer 242. The wiring 165 is electrically connected to the wiring 165 through an opening provided in the insulating layer 110. In the structure example illustrated in FIG. 15, the wiring 165 is formed using the same material in the same process as the conductive layers 112a and 107, and the conductive layer 166 is formed using the same material in the same process as the conductive layer 112b.

In a plan view, the pixel electrode 111 has a comb-like shape or a shape with a slit. Furthermore, the pixel electrode 111 overlaps with the common electrode 115. There is a portion where the pixel electrode 111 is not provided over the common electrode 115 in a region overlapping with the coloring layer.

Note that in the liquid crystal element 60, both the pixel electrode 111 and the common electrode 115 can have a comb-like top surface shape. Meanwhile, as illustrated in the display device 100D, only one of the pixel electrode 111 and the common electrode 115 has a comb-like top surface shape in the liquid crystal element 60, whereby the pixel electrode 111 and the common electrode 115 partly overlap with each other. In this structure, capacitance between the pixel electrode 111 and the common electrode 115 can be used as a storage capacitor, and thus a capacitor does not need to be provided additionally; accordingly, the aperture ratio of the display device can be increased.

The insulating layer 225 is provided on the substrate 152 side to cover the coloring layers 132R and 132G and the light-blocking layer 117. The insulating layer 225 serves as an overcoat that prevents diffusion of components contained in the coloring layers 132R and 132G and the like into the liquid crystal 262. The insulating layer 225 can serve as a planarization film. The insulating layer 225 can be formed using a light-transmitting organic resin.

Alignment films for controlling the alignment of the liquid crystal 262 can be provided on surfaces of the pixel electrode 111, the insulating layer 214, the insulating layer 225, and the like which are in contact with the liquid crystal 262.

The above is the description of the structure examples of the display devices.

### [Manufacturing Method Example of Display Device]

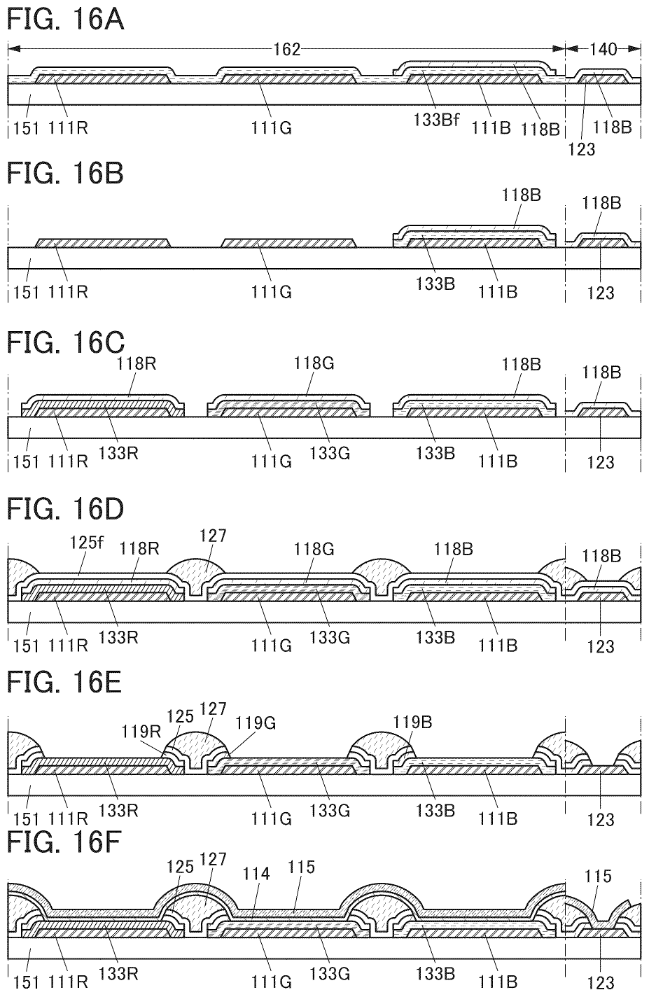

A method for manufacturing a display device having a metal maskless (MML) structure will be described below. Here, steps of fabricating light-emitting elements without using a fine metal mask will be described in detail. FIGS. 16A to 16F are cross-sectional views of three light-emitting elements included in the display portion 162 and the connection portion 140 in the fabrication steps.

For fabrication of the light-emitting element, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, screen printing (stencil), offset printing (planography), flexography (relief printing), gravure printing, or micro-contact printing), or the like.

In the method described below for manufacturing the display device, the island-shaped layer (the layer including the light-emitting layer) is formed not by using a fine metal mask but by processing a light-emitting layer formed on the entire surface with a photolithography method. Accordingly, a high-resolution display device or a display device with a high aperture ratio, which has been difficult to be formed so far, can be achieved. Moreover, light-emitting layers can be formed separately for the respective colors, enabling the display device to perform extremely clear display with high contrast and high display quality. Moreover, providing a sacrificial layer over the light-emitting layer can reduce damage to the light-emitting layer in the manufacturing process of the display device, resulting in an increase in reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by forming a light-emitting layer and performing processing three times by photolithography.

First, the pixel electrodes 111R, 111G, and 111B and the conductive layer 123 are formed over the substrate 151 provided with the transistors 205R, 205G, and 205B and the like (not illustrated) (FIG. 16A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. The conductive film can be processed by a wet etching method and/or a dry etching method.

Next, a film 133Bf to be the layer 133B later is formed over the pixel electrodes 111R, 111G, and 111B (FIG. 16A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed for the blue-, green-, and red-light-emitting elements in this order or the blue-, red-, and green-light-emitting elements in this order.

This enables the blue-light-emitting element to keep the favorable state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers can be formed for the red-, green-, and blue-light-emitting elements in this order.

As illustrated in FIG. 16A, the film 133Bf is not formed over the conductive layer 123. The film 133Bf can be formed only in a desired region using an area mask, for example. Employing a formation step using an area mask and a processing step using a resist mask enables a light-emitting element to be fabricated by a relatively easy process.

The upper temperature limit of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Therefore, the range of choices of the materials and the manufacturing method of the display device can be widened, thereby improving the manufacturing yield and the reliability.

Examples of the upper temperature limit include the glass transition point, the softening point, the melting point, the thermal decomposition temperature, and the 5% weight loss temperature, and the lowest one among the temperatures is preferable.

The film 133Bf can be formed by an evaporation method, specifically a vacuum evaporation method, for example. The film 133Bf can be formed by a transfer method, a printing method, an inkjet method, a coating method, or the like.

Next, a sacrificial layer 118B is formed over the film 133Bf and the conductive layer 123 (FIG. 16A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display device, resulting in an increase in reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 113B, and thus is preferably positioned outward from the end portion of the pixel electrode 111B, i.e., not used as the light-emitting region. This can suppress variation in the characteristics of the light-emitting elements and can improve reliability.

When the layer 133B covers the top and side surfaces of the pixel electrode 111B, the steps after the formation of the layer 133B can be performed without exposing the pixel electrode 111B. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the upper temperature limit of each compound included in the film 133Bf. The typical substrate temperature in formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high because the formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film formed at a higher temperature can be denser and have a higher barrier property. Therefore, forming the sacrificial layer at such a temperature can further reduce damage to the film 133Bf and improve the reliability of the light-emitting element.

Note that the same can be applied to the formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the sacrificial layer 118B can be formed by the above-described wet process.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid can be used. A chemical solution used for the wet etching treatment can be alkaline or acid.

As the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) can be used.

For example, a semiconductor material such as silicon or germanium can be used as a material with an affinity for the semiconductor manufacturing process. Alternatively, oxide or nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, oxide containing the above-described metal, such as titanium oxide or chromium oxide, or nitride such as titanium nitride, chromium nitride, or tantalum nitride can be used.

As the sacrificial layer 118B, a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. For the sacrificial layer 118B and the insulating layer 125, the same formation condition can be used or different formation conditions can be used. For example, when the sacrificial layer 118B is formed under conditions similar to those of the insulating layer 125, the sacrificial layer 118B can be an insulating layer having a high barrier property against at least one of water and oxygen. Meanwhile, since the sacrificial layer 118B is a layer a large part or the whole of which is to be removed in a later step, it is preferable that the processing of the sacrificial layer 118B be easy. Therefore, the sacrificial layer 118B is preferably formed with a substrate temperature lower than that for formation of the insulating layer 125.

An organic material can be used for the sacrificial layer 118B. For example, as the organic material, a material that can be dissolved in a solvent chemically stable with respect to at least the uppermost film of the film 133Bf can be used. Specifically, a material that is dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B can be formed using an organic material such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer.

For example, a stacked-layer structure of an organic film (e.g., a PVA film) formed by an evaporation method or the above wet process and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 16B).

Accordingly, as illustrated in FIG. 16B, the stacked-layer structure of the layer 133B and the sacrificial layer 118B remains over the pixel electrode 111B. In addition, the pixel electrodes 111R and 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching can be employed.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 16C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B. The sacrificial layers 118R and 118G can be formed using the same material or different materials.

Note that side surfaces of the layers 133B, 133G, and 133R are preferably perpendicular or substantially perpendicular to their formation surfaces. For example, the angle between the formation surfaces and these side surfaces is preferably greater than or equal to 60(and less than or equal to 90°.

As described above, the distance between adjacent layers in the layers 133B, 133G, and 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between facing end portions of adjacent layers in the layers 133B, 133G, and 133R. When the distance between the island-shaped EL layers is shortened in this manner, a high-resolution display device with a high aperture ratio can be provided.

Next, the insulating film 125f to be the insulating layer 125 later is formed to cover the pixel electrodes, the layers 133B, 133G, and 133R, and the sacrificial layers 118B, 118G, and 118R, and then the insulating layer 127 is formed over the insulating film 125f (FIG. 16D).

The insulating film 125f is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case deposition damage is reduced and a film with good coverage can be deposited. As the inorganic insulating film 125f, an aluminum oxide film is preferably formed by an ALD method, for example.

Alternatively, the insulating film 125f can be formed by a sputtering method, a CVD method, or a plasma CVD method that provides a higher deposition rate than an ALD method. In this case, a highly reliable display device can be manufactured with high productivity.

For example, the insulating film to be the insulating layer 127 is preferably formed by the aforementioned wet process (e.g., spin coating) using a photosensitive resin composite containing an acrylic resin. After the film formation, heat treatment (also referred to as pre-baking) is preferably performed to eliminate a solvent contained in the insulating film. Next, part of the insulating film is irradiated with visible light or ultraviolet rays as light exposure. Next, the region of the insulating film exposed to light is removed by development. Then, heat treatment (also referred to as post-baking) is performed. Accordingly, the insulating layer 127 illustrated in FIG. 16D can be formed. Note that the shape of the insulating layer 127 is not limited to the shape illustrated in FIG. 16D. For example, the top surface of the insulating layer 127 can include one or more of a convex surface, a concave surface, and a flat surface. The insulating layer 127 can cover a side surface of an end portion of at least one of the insulating layer 125, the sacrificial layer 118B, the sacrificial layer 118G, and the sacrificial layer 118R.

Next, as illustrated in FIG. 16E, etching treatment is performed using the insulating layer 127 as a mask to remove portions of the insulating film 125f and the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Note that portions of the sacrificial layers 118B, 118G, and 118R can remain in positions overlapping with the insulating layers 127 and 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, by providing the insulating layers 127 and 125 and the sacrificial layers 118R, 118G, and 118B, poor connection due to a disconnected portion and an increase in electric resistance due to a locally thinned portion can be inhibited from occurring in the common layer 114 and the common electrode 115 between the light-emitting elements. Thus, the display device of one embodiment of the present invention can have improved display quality.

Next, the common layer 114 and the common electrode 115 are formed in this order over the insulating layer 127 and the layers 133B, 133G, and 133R (FIG. 16F).

The common layer 114 can be formed by an evaporation method (including a vacuum evaporation method), a transfer method, a printing method, an inkjet method, a coating method, or the like.

The common electrode 115 can be formed by a sputtering method or a vacuum evaporation method, for example. Alternatively, a film formed by an evaporation method and a film formed by a sputtering method can be stacked.

As described above, in the method for manufacturing the display device of one embodiment of the present invention, the island-shaped layers 133R, 133G, and 133B are formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layers 133R, 133G, and 133B can be inhibited from being in contact with each other in the adjacent subpixels. As a result, generation of leakage current between the subpixels can be inhibited. This can prevent crosstalk due to unintended light emission, so that a display device with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. Thus, a connection defect due to a disconnection portion and an increase in electric resistance due to a local thinning portion can be inhibited from occurring in the common layer 114 and the common electrode 115. Hence, the display device of one embodiment of the present invention achieves both high resolution and high display quality.

The above is the description of the manufacturing method example of the display device.

At least part of this embodiment can be implemented in combination with any of the other embodiments described in this specification, as appropriate.

### Embodiment 3

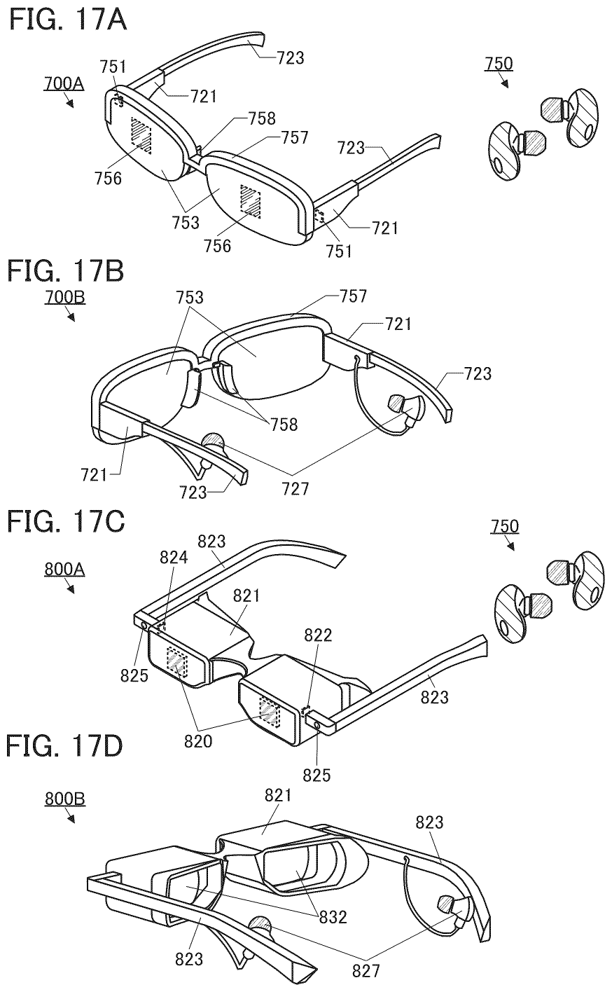

In this embodiment, electronic devices of embodiments of the present invention will be described with reference to FIGS. 17A to 17D, FIGS. 18A to 18F, and FIGS. 19A to 19G.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high definition, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment can include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 17A to 17D. The wearable devices have at least one of a function of displaying AR contents, a function of displaying VR contents, a function of displaying substitutional reality (SR) contents, and a function of displaying mixed reality (MR) contents. The electronic device having a function of displaying contents of at least one of AR, VR, SR, MR, and the like enables the user to feel a higher level of immersion.

An electronic device 700A illustrated in FIG. 17A and an electronic device 700B illustrated in FIG. 17B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side can be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential can be provided.

The electronic devices 700A and 700B are provided with a battery so that they can be charged wirelessly and/or by wire.

A touch sensor module can be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 17C and an electronic device 800B illustrated in FIG. 17D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 17C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras can be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just can be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A can include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B can each include an input terminal. To the input terminal, a cable for supplying a video signal from a video output device or the like, power for charging the battery provided in the electronic device, and the like can be connected.

The electronic device of one embodiment of the present invention can have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 17A has a function of transmitting information to the earphones 750 with the wireless communication function. As another example, the electronic device 800A in FIG. 17C has a function of transmitting information to the earphones 750 with the wireless communication function.

The electronic device can include an earphone portion. The electronic device 700B in FIG. 17B includes earphone portions 727. For example, the earphone portion 727 can be connected to the control portion by wire. Part of a wiring that connects the earphone portion 727 and the control portion can be positioned inside the housing 721 or the mounting portion 723.

Similarly, the electronic device 800B in FIG. 17D includes earphone portions 827. For example, the earphone portion 827 can be connected to the control portion 824 by wire. Part of a wiring that connects the earphone portion 827 and the control portion 824 can be positioned inside the housing 821 or the mounting portion 823. Alternatively, the earphone portions 827 and the mounting portions 823 can include magnets. This is preferable because the earphone portions 827 can be fixed to the mounting portions 823 with magnetic force and thus can be easily housed.

The electronic device can include an audio output terminal to which earphones, headphones, or the like can be connected. The electronic device can include one or both of an audio input terminal and an audio input mechanism. As the audio input mechanism, a sound collecting device such as a microphone can be used, for example. The electronic device can have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

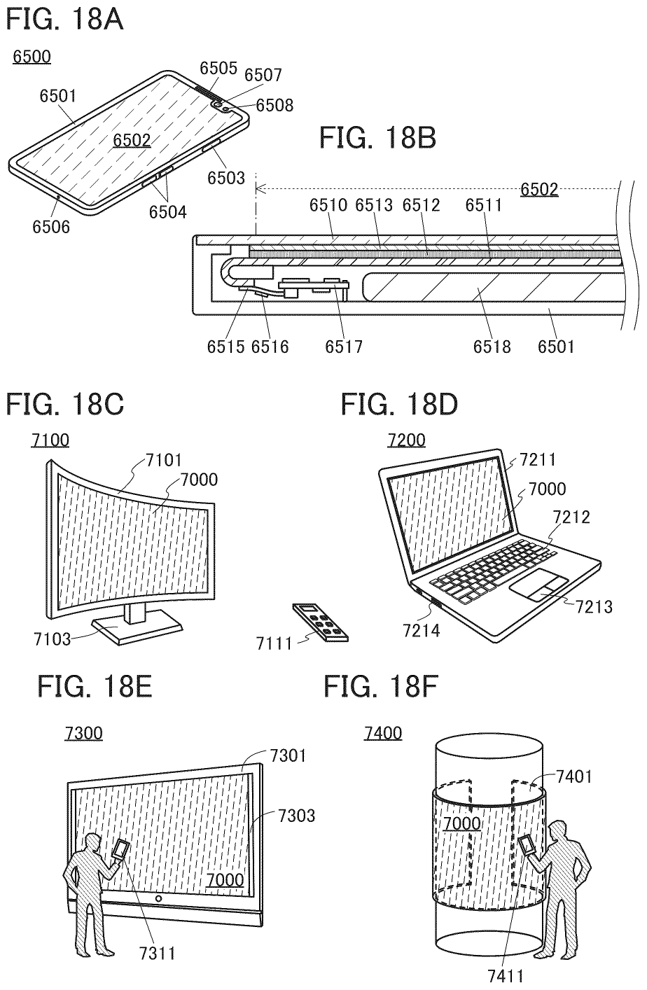

An electronic device 6500 illustrated in FIG. 18A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 18B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 18C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 18C can be performed with an operation switch provided in the housing 7101 and a separate remote controller 7111. Alternatively, the display portion 7000 can include a touch sensor, and the television device 7100 can be operated by touch on the display portion 7000 with a finger or the like. The remote controller 7111 can be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 18D illustrates an example of a laptop personal computer. The laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 18E and 18F illustrate examples of digital signage.

Digital signage 7300 illustrated in FIG. 18E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 18F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 18E and 18F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIGS. 18E and 18F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

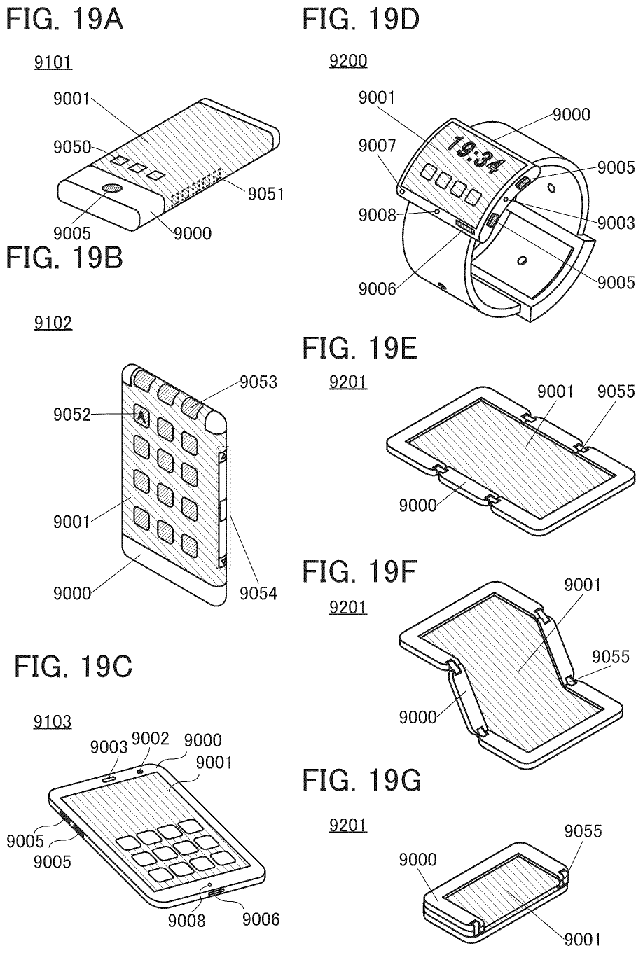

Electronic devices illustrated in FIGS. 19A to 19G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 19A to 19G, the display device of one embodiment of the present invention can be used in the display portion 9001.

The electronic devices illustrated in FIGS. 19A to 19G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices can include a plurality of display portions. The electronic devices can be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 19A to 19G will be described in detail below.

FIG. 19A is a perspective view of a portable information terminal 9101. The portable information terminal 9101 can be used as a smartphone, for example. The portable information terminal 9101 can include the speaker 9003, the connection terminal 9006, the sensor 9007, or the like. The portable information terminal 9101 can display text and image information on its plurality of surfaces. FIG. 19A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like can be displayed at the position where the information 9051 is displayed.

FIG. 19B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 19C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 19D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation can be performed by wireless power feeding.

FIGS. 19E to 19G are perspective views of a foldable portable information terminal 9201. FIG. 19E is a perspective view illustrating the portable information terminal 9201 that is opened. FIG. 19G is a perspective view illustrating the portable information terminal 9201 that is folded. FIG. 19F is a perspective view illustrating the portable information terminal 9201 that is shifted from one of the states in FIGS. 19E and 19G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with any of the other embodiments described in this specification, as appropriate.

### Example

The transistor of one embodiment of the present invention was fabricated. The cross-sectional observation and evaluation results of the electrical characteristics and the reliability of the transistor are described below.

In this example, the transistor described in Embodiment 1 with reference to FIG. 1 was fabricated on the basis of the fabrication method described above.

As the insulating layer 12, an approximately 30-nm thick silicon nitride film formed by a plasma CVD method was used. As the conductive layer 24, a stacked film including an approximately 10-nm thick ITSO film, an approximately 300-nm thick copper film, and an approximately 100-nm thick ITSO film each formed by a sputtering method was used. As the insulating layer 41, a stacked film including an approximately 100-nm thick silicon nitride film, an approximately 500-nm thick silicon oxynitride film, and an approximately 150-nm thick silicon nitride film each formed by a plasma CVD method was used. As the conductive layer 25, an approximately 100-nm thick ITSO film formed by a sputtering method was used. After the openings (openings 20, 15a, and 15b) reaching the insulating layer 12 were formed in the insulating layer 41, an approximately 35-nm thick In—Ga—Zn oxide film was formed by a sputtering method as the semiconductor layer 21, which was followed by one-hour heat treatment at 350° C. with the use of an electric furnace in a CDA atmosphere. After that, the semiconductor layer 21 was processed. As the insulating layer 22, a 50-nm-thick silicon oxynitride film formed at a substrate temperature of 350° C. by a plasma CVD method was used. As the conductive layer 23, a stacked film including an approximately 50-nm thick titanium film, an approximately 200-nm thick aluminum film, and an approximately 50-nm thick titanium film each formed by a sputtering method was used. As the insulating layer 44, an approximately 300-nm thick silicon oxynitride film formed at a substrate temperature of 350° C. by a plasma CVD method was used. After the formation of the insulating layer 44, one-hour heat treatment was performed at 300° C. with the use of the electric furnace in a CDA atmosphere.

The transistor was fabricated in the above manner.

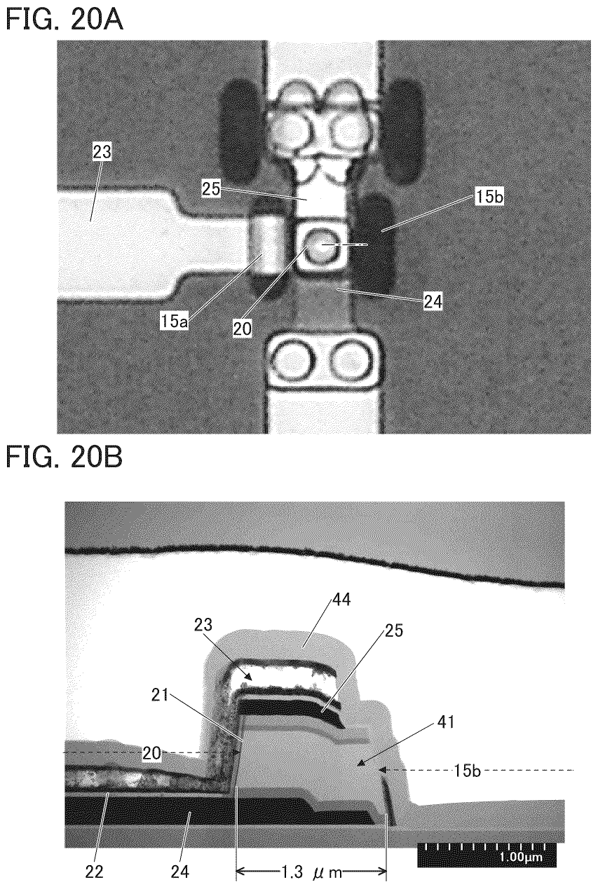

FIG. 20A shows an optical micrograph of the manufactured transistor and its periphery. The opening 20 is located in the center, and the openings 15a and 15b are located on both right and left sides of the opening 20. The opening 15a partly overlaps with the conductive layer 23. The diameter of the opening 20 was approximately 2 μm.

FIG. 20B shows a cross-sectional scanning transmission electron microscope (STEM) image taken along the dashed-dotted line in FIG. 20A. The distance from the sidewall of the opening 20 to the sidewall of the opening 15b (the width of the insulating layer 41) was approximately 1.3 μm.

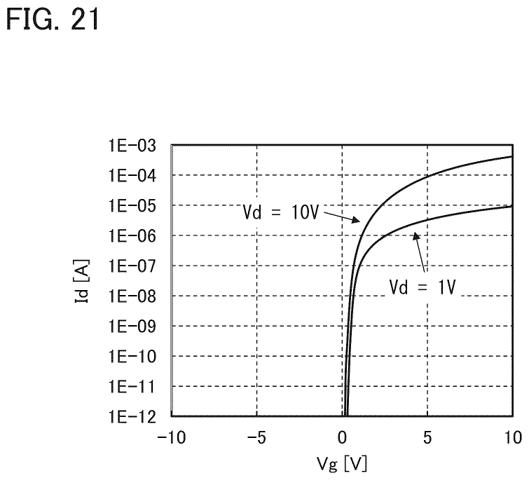

FIG. 21 shows Id-Vg characteristics of the transistor. The vertical axis represents a source-drain current (Id) on a logarithmic scale and the horizontal axis represents a source-gate voltage (Vg). FIG. 21 shows the characteristics at Vd of 1 V and 10 V. As shown in FIG. 21, favorable normally-off electrical characteristics were found.

Furthermore, the transistor was subjected to a PBTS test. The stress voltage (Vg) was 10 V, the temperature was 60° C., and the test time was one hour. As a result, the amount of change in threshold voltage was approximately 0.20 V while the initial threshold voltage was 0.49 V, which revealed extremely high reliability.

According to this example, it was confirmed that the transistor of one embodiment of the present invention exhibits favorable electrical characteristics and high reliability.

This application is based on Japanese Patent Application Serial No. 2023-099244 filed with Japan Patent Office on Jun. 16, 2023, the entire contents of which are hereby incorporated by reference.

What is claimed is:

1. A semiconductor device comprising:
a transistor; and
a first insulating layer,
wherein the transistor comprises a first conductive layer, a second conductive layer, a third conductive layer, a semiconductor layer, and a second insulating layer,
wherein the first insulating layer comprises a first layer and a second layer over the first layer,
wherein the first insulating layer is over the first conductive layer and comprises a first opening reaching the first conductive layer,
wherein the second conductive layer is over the second layer,
wherein the semiconductor layer comprises a part in contact with the first conductive layer, a part in contact with the second conductive layer, and a part in contact with a side surface of the first layer inside the first opening,
wherein the second insulating layer covers the semiconductor layer in the first opening,
wherein the third conductive layer covers the second insulating layer in the first opening,
wherein the first insulating layer comprises a second opening at a position different from the first opening,
wherein the second insulating layer comprises a part in contact with the first layer inside the second opening,
wherein the first layer comprises an oxide insulating film, and
wherein the second layer comprises an insulating film having an oxygen barrier property.

2. The semiconductor device according to claim 1,
wherein the second opening is at a position not overlapping with the second conductive layer in a plan view.

3. The semiconductor device according to claim 2,
wherein the second opening comprises a part overlapping with the third conductive layer.

4. The semiconductor device according to claim 2,
wherein the second opening comprises a part overlapping with the first conductive layer.

5. The semiconductor device according to claim 1,
wherein the second opening penetrates the second layer and reaches the first layer.

6. The semiconductor device according to claim 5,
wherein the first layer comprises a depression overlapping with the second opening, and
wherein the second insulating layer is in contact with a surface of the depression of the first layer inside the second opening.

7. The semiconductor device according to claim 1,
wherein the second opening penetrates the second layer and the first layer, and
wherein the second insulating layer is in contact with a side surface of the first insulating layer inside the second opening.

8. The semiconductor device according to claim 1,
wherein the first insulating layer comprises a third layer below the first layer, and
wherein the second opening penetrates the second layer and the first layer and reaches the third layer.

9. The semiconductor device according to claim 1,
wherein the first insulating layer comprises a third layer below the first layer, and
wherein the second opening penetrates the second layer, the first layer, and the third layer.

10. The semiconductor device according to claim 1,
wherein the first layer comprises silicon oxide, and
wherein the second layer comprises silicon nitride or aluminum oxide.

11. The semiconductor device according to claim 1,
wherein a shortest distance between the first opening and the second opening is greater than or equal to 0.1 μm and less than or equal to 100 μm.

12. A method for manufacturing a semiconductor device, comprising the steps of:
forming a first layer and a second layer over a first conductive layer;
forming a second conductive layer over the second layer;
forming, in the first layer and the second layer, a first opening reaching the first conductive layer and a second opening at a position apart from the first opening;
performing heat treatment after forming a semiconductor film that covers the first opening and the second opening and is in contact with each of the first conductive layer and the second conductive layer;
etching a part of the semiconductor film to expose the second opening;
forming an insulating layer covering the semiconductor film and the second opening; and
forming, over the insulating layer, a third conductive layer overlapping with the semiconductor layer,
wherein the first layer comprises an oxide insulating film, and
wherein the second layer comprises an insulating film having an oxygen barrier property.
